(19) United States
(12) Patent Application Publication
(10) Pub. No.: US 2023/0268398 A1
(43) Pub. Date: Aug. 24, 2023

(54) POWER SEMICONDUCTOR DEVICE AND METHOD FOR MANUFACTURING POWER SEMICONDUCTOR DEVICE

(71) Applicant: Mitsubishi Electric Corporation, Tokyo (JP)

(72) Inventors: Katsumi NAKAMURA, Tokyo (JP); Naoyuki TAKEDA, Tokyo (JP); Mikihito SUZUKI, Tokyo (JP); Koji TANAKA, Tokyo (JP)

(73) Assignee: Mitsubishi Electric Corporation, Tokyo (JP)

(21) Appl. No.: 18/062,446

(22) Filed: Dec. 6, 2022

(30) Foreign Application Priority Data
Feb. 24, 2022 (JP) 2022-026290

(51) Int. Cl. H01L 29/32; H01L 27/06; H01L 29/861; H01L 29/739; H01L 21/22; H01L 21/265

(52) U.S. Cl. CPC H01L 29/32; H01L 27/0664; H01L 29/8613; H01L 29/7397; H01L 21/221; H01L 21/26513

(57) ABSTRACT

In an RFC diode, a semiconductor substrate includes an n− drift layer, an n buffer layer, and a diffusion layer provided between and in contact with the n buffer layer and a second metal layer. The diffusion layer includes an n+ cathode layer provided in contact with the n buffer layer and the second metal layer in a diode region. The n+ cathode layer includes a first n+ cathode layer in contact with the second metal layer and a second n+ cathode layer provided between the first n+ cathode layer and the n buffer layer in contact with the n buffer layer. Crystal defect density of the first n+ cathode layer is higher than crystal defect density of another diffusion layer.

### FIELD OF THE INVENTION

The present disclosure relates to a power semiconductor device.

### DESCRIPTION OF THE BACKGROUND ART

Japanese Patent Application Laid-Open No. 2017-201644 discloses a power diode having two n buffer layers. Between the two n buffer layers, a low carrier lifetime control layer is provided in an n buffer layer in contact with a high concentration n+ layer on the cathode side. By the above, tail current is suppressed during recovery operation of the power diode, that is, reverse recovery switching operation, and as a result, recovery loss is reduced.

The power diode of Japanese Patent Application Laid-Open No. 2017-201644 basically has two n buffer layers having different carrier lifetimes. For this reason, the power diode of Japanese Patent Application Laid-Open No. 2017-201644 can shift a trade-off characteristic between on-voltage and switching loss, which are performance indexes of a power semiconductor device, to the high-speed side without using a carrier lifetime control method. Here, the carrier lifetime control method is, for example, control using a charged particle system of an electron beam, proton, or helium, or a heavy metal system of platinum.

However, there has been a problem that voltage holding capability when a reverse bias is applied to a main junction, which is an action of an n buffer layer, is deteriorated, and voltage interrupting capability, which is basic performance of a power semiconductor, such as reduction of off-loss due to reduction of leakage current during voltage holding, is deteriorated.

Further, there has been a problem that it is difficult to realize high-temperature operation which is a trend in power semiconductor devices due to increase in leakage current during voltage holding.

### SUMMARY

An object of a technique of the present disclosure is to shift a trade-off characteristic between on-voltage and switching loss to the high-speed side regardless of a carrier lifetime control method in a power semiconductor device, and to realize low off-loss and high temperature operation.

The power semiconductor device of the present disclosure includes a semiconductor substrate, a first metal layer, and a second metal layer.

The semiconductor substrate has a first main surface and a second main surface facing each other.

The first metal layer is provided on the first main surface of the semiconductor substrate.

The second metal layer is provided on the second main surface of the semiconductor substrate.

The semiconductor substrate includes a drift layer of a first conductivity type, a buffer layer of the first conductivity type, and a diffusion layer.

The buffer layer is provided between the drift layer and the second main surface.

The diffusion layer is provided between and in contact with the buffer layer and the second metal layer.

A partial region in plan view of the power semiconductor device is a diode region that operates as a diode.

The diffusion layer includes a cathode layer of a first conductivity type.

The cathode layer is provided in contact with the buffer layer and the second metal layer in at least a part of the diode region.

The cathode layer includes a first cathode layer and a second cathode layer.

The first cathode layer has one impurity concentration peak point and is in contact with the second metal layer.

The second cathode layer has one impurity concentration peak point and is provided between the first cathode layer and the buffer layer so as to be in contact with the buffer layer.

Crystal defect density of the first cathode layer is higher than crystal defect density of another diffusion layer.

In the power semiconductor device of the present disclosure, the crystal defect density of the first cathode layer is higher than crystal defect density of another diffusion layer.

Therefore, it is possible to shift a trade-off characteristic between on-voltage and switching loss to the high-speed side regardless of a carrier lifetime control method, and to realize low off-loss and high temperature operation.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a power semiconductor device;

FIG. 2 is a cross-sectional view of a conventional RFC diode taken along line A1-A1′ in FIG. 1;

FIG. 3 is a cross-sectional view of the RFC diode according to a first preferred embodiment taken along line A1-A1′ in FIG. 1;

FIG. 4 is a diagram illustrating impurity concentration of a diffusion layer in an RFC diode 1001 along lines B-B′ and C-C′ in FIG. 3;

FIG. 5 is a diagram illustrating a PL spectrum in a cathode structure of a conventional RFC diode and the RFC diode according to the first preferred embodiment;

FIG. 6 is a diagram illustrating a trade-off characteristic between on-voltage and switching loss for the conventional RFC diode and the RFC diode according to the first preferred embodiment;

FIG. 7 is a diagram illustrating an output characteristic of the RFC diode according to the first preferred embodiment, with a relationship of a dose amount between a second n+ cathode layer and a second p cathode layer as a parameter;

FIG. 8 is a diagram illustrating an output characteristic of the conventional RFC diode and the RFC diode according to the first preferred embodiment;

FIG. 9 is a diagram illustrating operation temperature dependency of on-voltage of the conventional RFC diode and the conventional RFC diode according to the first preferred embodiment;

FIG. 10 is a diagram illustrating a leakage characteristic of the conventional RFC diode and the RFC diode according to the first preferred embodiment when a reverse bias is applied to a main junction;

FIG. 11 is a diagram illustrating a waveform of the conventional RFC diode and the RFC diode according to the first preferred embodiment during recovery operation in a small current mode;

FIG. 12 is a diagram illustrating a relationship between snap-off voltage and power supply voltage during recovery operation for the conventional RFC diode and the RFC diode according to the first preferred embodiment;

FIG. 13 is a diagram illustrating a change in on-voltage at the time of a continuous energization test for the conventional RFC diode and the RFC diode according to the first preferred embodiment;

FIG. 14 is a cross-sectional view of the RFC diode of a second preferred embodiment taken along line A1-A1′ of FIG. 1;

FIG. 15 is a diagram illustrating impurity concentration in a diffusion layer of the RFC diode of the second preferred embodiment along lines B-B′ and C-C′ in FIG. 14;

FIG. 16 is a diagram illustrating a relationship between snap-off voltage and power supply voltage during recovery operation in a small current mode for the RFC diodes of the first and second preferred embodiments;

FIG. 17 is a cross-sectional view of the RFC diode according to a third preferred embodiment taken along line A1-A1′ in FIG. 1;

FIG. 18 is a diagram illustrating impurity concentration in a diffusion layer of the RFC diode according to the third preferred embodiment along lines B-B′ and C-C′ in FIG. 17;

FIG. 19 is a diagram illustrating PL spectrums in a first n buffer layer and a second n buffer layer of the RFC diode according to the third preferred embodiment;

FIG. 20 is a diagram illustrating a relationship between PL intensity and annealing temperature in traps B and C in a second n buffer layer;

FIG. 21 is a diagram illustrating a trade-off characteristic between on-voltage and switching loss for the conventional RFC diode and the RFC diode according to the third preferred embodiment;

FIGS. 22 to 30 are cross-sectional views each illustrating a method for manufacturing the RFC diode according to the first preferred embodiment;

FIG. 31 is a flowchart illustrating a process after a forming processing of a surface protective film in the method for manufacturing the RFC diode according to the first preferred embodiment;

FIG. 32 is a flowchart illustrating a process after the forming processing of a surface protective film in the method for manufacturing the RFC diode according to the third preferred embodiment;

FIG. 33 is a cross-sectional view of a conventional pin diode taken along line A1-A1′ of FIG. 1;

FIG. 34 is a cross-sectional view of a pin diode of a sixth preferred embodiment taken along line A1-A1′ of FIG. 1;

FIG. 35 is a cross-sectional view of a pin diode according to a variation of the sixth preferred embodiment taken along line A1-A1′ of FIG. 1;

FIG. 36 is a diagram illustrating a trade-off characteristic between on-voltage and switching loss for the conventional pin diode and the pin diodes according to the sixth preferred embodiment and the variation of the sixth preferred embodiment;

FIG. 37 is a flowchart illustrating a process after a forming process of a surface protective film in the method for manufacturing the pin diode of the sixth preferred embodiment;

FIG. 38 is a cross-sectional view of an RC-IGBT according to a seventh preferred embodiment taken along line A-A′ of FIG. 1;

FIG. 39 is a cross-sectional view of the RC-IGBT according to a first variation of the seventh preferred embodiment, taken along line A-A′ of FIG. 1;

FIG. 40 is a cross-sectional view of the RC-IGBT according to a second variation of the seventh preferred embodiment, taken along line A-A′ of FIG. 1;

FIG. 41 is a cross-sectional view of the RC-IGBT according to an eighth preferred embodiment taken along line A-A′ of FIG. 1;

FIG. 42 is a cross-sectional view of the RC-IGBT according to a first variation of the eighth preferred embodiment, taken along line A-A′ of FIG. 1;

FIG. 43 is a cross-sectional view of the RC-IGBT according to a second variation of the eighth preferred embodiment, taken along line A-A′ of FIG. 1;

FIG. 44 is a cross-sectional view of an RC-IGBT according to a ninth preferred embodiment taken along line A-A′ of FIG. 1;

FIG. 45 is a cross-sectional view of the RC-IGBT according to a first variation of the ninth preferred embodiment, taken along line A-A′ of FIG. 1;

FIG. 46 is a cross-sectional view of the RC-IGBT according to a second variation of the ninth preferred embodiment, taken along line A-A′ of FIG. 1;

FIG. 47 is a cross-sectional view of the RC-IGBT according to a tenth preferred embodiment taken along line A-A′ of FIG. 1;

FIG. 48 is a cross-sectional view of the RC-IGBT according to a first variation of the tenth preferred embodiment, taken along line A-A′ of FIG. 1;

FIG. 49 is a cross-sectional view of the RC-IGBT according to a second variation of the tenth preferred embodiment, taken along line A-A′ of FIG. 1; and

FIG. 50 is a cross-sectional view of the IGBT according to an eleventh preferred embodiment taken along line A-A′ of FIG. 1.

### DESCRIPTION OF THE PREFERRED EMBODIMENTS

Hereinafter, a preferred embodiment will be described with reference to the attached drawings. Note that the drawings are schematically illustrated, and a mutual relationship between sizes and positions of images illustrated in different drawings is not necessarily accurately described, and can be appropriately changed. Further, in description shown below, similar constituent elements are illustrated with the same reference numerals. This similarly applies to their names and functions. Therefore, there is a case where detailed description of them is omitted.

Further, in description below, terms meaning specific positions and directions such as “upper”, “lower”, “side”, “bottom”, “front”, or “back” may be used, but these terms are used for convenience to facilitate understanding of content of a preferred embodiment, and do not limit directions in actual implementation.

Further, in description below, regarding a conductivity type of a semiconductor, a first conductivity type is an n-type and the second conductivity type is a p-type, but the conductivity types may be opposite.

Further, regarding a conductivity type of a semiconductor, n− represents that n− type impurity concentration is smaller than n, and n+ represents that n-type impurity concentration is larger than n. Similarly, p− represents that p-type impurity concentration is smaller than p, and p+ represents that p-type impurity concentration larger than p.

### A. First Preferred Embodiment

<A-1. Configuration>

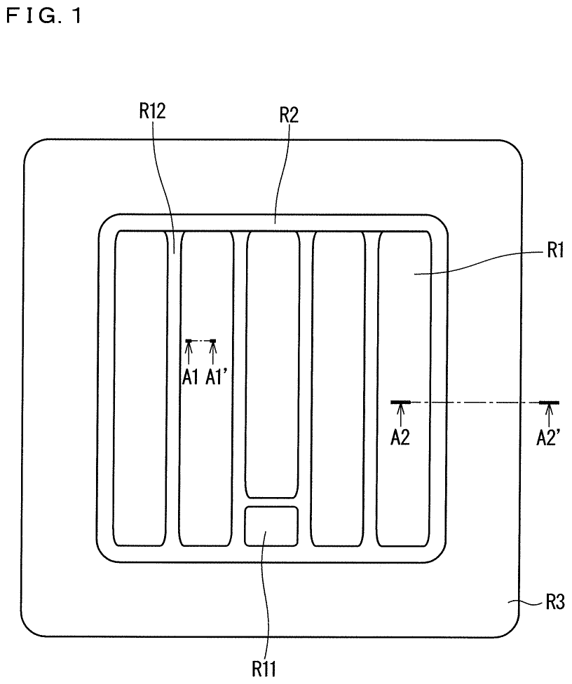

FIG. 1 schematically illustrates a planar structure of a vertical power semiconductor device. As illustrated in the diagram, a plurality of active cell regions R1 are formed in a central portion, a surface gate wiring portion R12 is provided between two of the active cell regions R1, and a gate pad portion R11 is further provided in a partial region.

An intermediate region R2 is formed surrounding the active cell region R1, the gate pad portion R11, and the front gate wiring portion R12, and a termination region R3 is provided further surrounding a periphery of the intermediate region R2.

The active cell region R1 described above is an element formation region that ensures basic performance of the power semiconductor device. Then, a peripheral region including the intermediate region R2 and the termination region R3 is provided for maintaining withstand voltage including reliability. Among them, the intermediate region R2 is a region in which the active cell region R1 and the termination region R3 are joined to each other, which guarantees breakdown resistance during dynamic operation of the power semiconductor and supports original performance of a semiconductor element in the active cell region R1. Further, the termination region R3 guarantees withstand voltage retention in a static state, stability and reliability of a withstand voltage characteristic, suppresses failure in breakdown resistance during dynamic operation, and supports original performance of the active cell region R1.

However, in a case where the power semiconductor device is a diode, the surface gate wiring portion R12 and the gate pad portion R11 do not need to be provided.

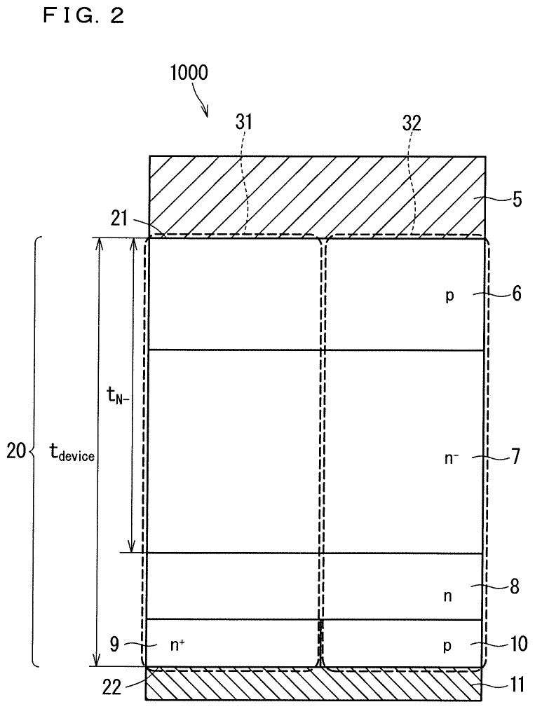

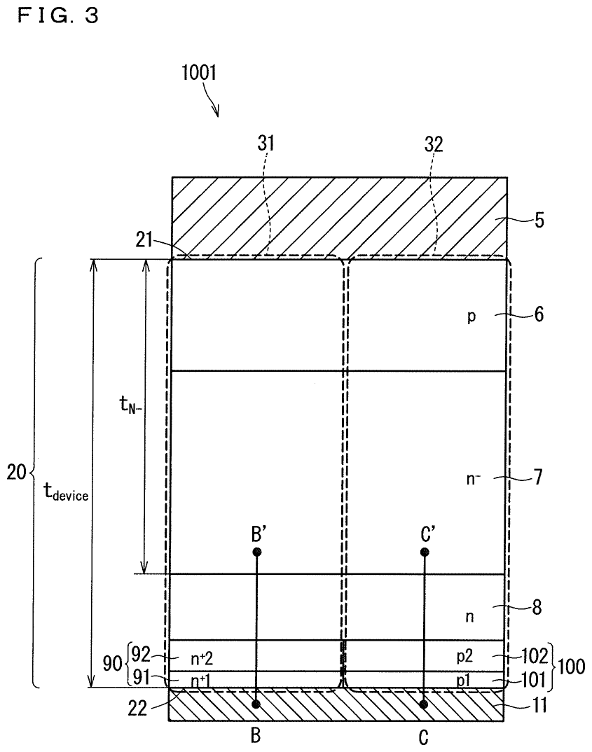

FIGS. 2 and 3 illustrate a cross-sectional configuration of a Relaxed Field of Cathode (RFC) diode, which is an example of the power semiconductor device, taken along line A1-A1′ in FIG. 1. FIG. 2 is a cross-sectional view of a conventional RFC diode 1000, and FIG. 3 is a cross-sectional view of an RFC diode 1001 according to a first preferred embodiment. In the diagrams, the conventional RFC diode 1000 may be referred to as Con. RFC diode, and the RFC diode 1001 according to the first preferred embodiment may be referred to as New RFC diode 1.

First, the conventional RFC diode 1000 will be described. The RFC diode 1000 includes a semiconductor substrate 20, a first metal layer 5, and a second metal layer 11. The semiconductor substrate 20 includes a first main surface 21 which is an upper main surface in FIGS. 2 and 3, and a second main surface 22 facing the first main surface 21. The first metal layer 5 is provided on the first main surface 21 of the semiconductor substrate 20, and the second metal layer 11 is provided on the second main surface 22 of the semiconductor substrate 20.

The semiconductor substrate 20 includes a p anode layer 6, an n− drift layer 7, an n buffer layer 8, an n+ cathode layer 9, and a p cathode layer 10. The p anode layer 6 is provided between the n− drift layer 7 and the first main surface 21. A surface of the p anode layer 6 constitutes the first main surface 21 of the semiconductor substrate 20. The n buffer layer 8 is provided between the n− drift layer 7 and the second main surface 22. The n+ cathode layer 9 and the p cathode layer 10 are provided between the n buffer layer 8 and the second main surface 22. Surfaces of the n+ cathode layer 9 and the p cathode layer 10 constitute the second main surface 22 of the semiconductor substrate 20 and are in contact with the second metal layer 11.

A pin diode region 31 is constituted by a vertical region including the n+ cathode layer 9, that is, the n+ cathode layer 9 and the n buffer layer 8, the n− drift layer 7, and the p anode layer 6 above the n+ cathode layer 9. Further, a pnp transistor region 32 is constituted by a vertical region including the p cathode layer 10, that is, the p cathode layer and the n buffer layer 8, the n− drift layer 7, and the p anode layer 6 above the p cathode layer. As described above, the RFC diode 1000 has a configuration in which the pin diode region 31 and the pnp transistor region 32 are alternately arranged in plan view.

The n− drift layer 7 is formed using a Si wafer having impurity concentration Cₙ₋ of 1.0×10¹² atoms/cm³ or more and 1.0×10¹⁵ atoms/cm³ or less. That is, the semiconductor substrate 20 is a Si substrate. Device thickness t_{device}, which is thickness of the semiconductor substrate 20, is 40 μm or more and 700 μm or less.

The p anode layer 6 has impurity concentration of 1.0×10¹⁶ atoms/cm³ or more on a surface in contact with the first metal layer 5, that is, on the first main surface 21, peak impurity concentration of 2.0×10¹⁶ atoms/cm³ or more and 1.0×10¹⁸ atoms/cm³ or less, and a depth of 2.0 μm or more and 10.0 μm or less.

In the n buffer layer 8, peak impurity concentration C_{nb, p} is 1.0×10¹⁵ atoms/cm³ or more and 5.0×10¹⁶ atoms/cm³ or less, and the depth X_{j, nb} is 1.2 μm or more and 50 μm or less.

Next, the RFC diode 1001 according to the first preferred embodiment will be described. The RFC diode 1001 is different from the conventional RFC diode 1000 in that the RFC diode 1001 includes an n+ cathode layer 90 instead of the n+ cathode layer 9 and a p cathode layer 100 instead of the p cathode layer 10. In the RFC diode 1001, the n+ cathode layer 90 has a two-layer structure including a first n+ cathode layer 91 and a second n+ cathode layer 92, and the p cathode layer 100 has a two-layer structure including a first p cathode layer 101 and a second p cathode layer 102. Note that the first p cathode layer 101 is also referred to as a first diffusion layer, and the second p cathode layer 102 is also referred to as a second diffusion layer.

Hereinafter, the first n+ cathode layer 91 may be referred to as a first cathode layer, and its conductivity type may be denoted as n+1 in the diagram. Further, the second n+ cathode layer 92 may be referred to as a second cathode layer, and its conductivity type may be denoted as n+2 in the diagram. A conductivity type of the first p cathode layer 101 may be referred to as p1. A conductivity type of the second p cathode layer 102 may be referred to as p2.

The first n+ cathode layer 91 and the first p cathode layer 101 are in contact with the second metal layer 11. The second n+ cathode layer 92 and the second p cathode layer 102 are in contact with the n buffer layer 8. Lower surfaces of the first n+ cathode layer 91 and the first p cathode layer 101 in FIG. 3 constitute the second main surface 22 of the semiconductor substrate 20.

The first n+ cathode layer 91 has impurity concentration of 1.0×10¹⁸ atoms/cm³ or more and 1.0×10²⁰ atoms/cm³ or less on a surface in contact with the second metal layer 11, that is, on the second main surface 22, and has a depth of 0.1 μm or more and 0.2 μm or less.

The second n+ cathode layer 92 has peak impurity concentration of 1.0×10¹⁷ atoms/cm³ or more and 1.0×10¹⁹ atoms/cm³ or less and a depth of 0.3 μm or more and 0.5 μm or less.

The first p cathode layer 101 has impurity concentration of 1.0×10¹⁷ atoms/cm³ or more and 1.0×10¹⁹ atoms/cm³ or less on a surface in contact with the second metal layer 11, that is, on the second main surface 22, and has a depth of 0.1 μm or more and 0.2 μm or less.

The second p cathode layer 102 has peak impurity concentration of 1.0×10¹⁶ atoms/cm³ or more and 1.0×10¹⁸ atoms/cm³ or less and a depth of 0.3 μm or more and 0.5 μm or less.

In the present preferred embodiment, the n+ cathode layer 90 is composed of two layers of the first n+ cathode layer 91 and the second n+ cathode layer 92, and the p cathode layer 100 is composed of two layers of the first p cathode layer 101 and the second p cathode layer 102. A purpose of each layer is as described below.

The first n+ cathode layer 91 and the first p cathode layer 101 are diffusion layers for improving contact property with the second metal layer 11. Crystal defect density of the first n+ cathode layer 91 is higher than crystal defect density of the second n+ cathode layer 92, the first p cathode layer 101, and the n buffer layer 8. The second n+ cathode layer 92 and the second p cathode layer 102 are diffusion layers for controlling performance of the RFC diode 1001 and ensuring normal on-operation.

An impurity profile and a depth of the diffusion layer may be determined by a range (RP) at the time of ion implantation from a characteristic of an annealing technique at the time of formation of the diffusion layer. Here, the range is defined as a depth from second main surface 22 to a position of peak concentration of each diffusion layer. Therefore, a range at the time of ion implantation when the first n+ cathode layer 91, the second n+ cathode layer 92, the first p cathode layer 101, and the second p cathode layer 102 are formed is determined by Equation (1) below so that the layers do not interfere with each other.

Rₙ₊₂/Rₙ₊₁=5.0,R_{P2}/R_{P1}=5.0 (1)

Here, Rₙ₊₁, Rₙ₊₂, Rₚ₁, and Rₚ₂ represent ranges (m) of the first n+ cathode layer 91, the second n+ cathode layer 92, the first p cathode layer 101, and the second p cathode layer 102, respectively.

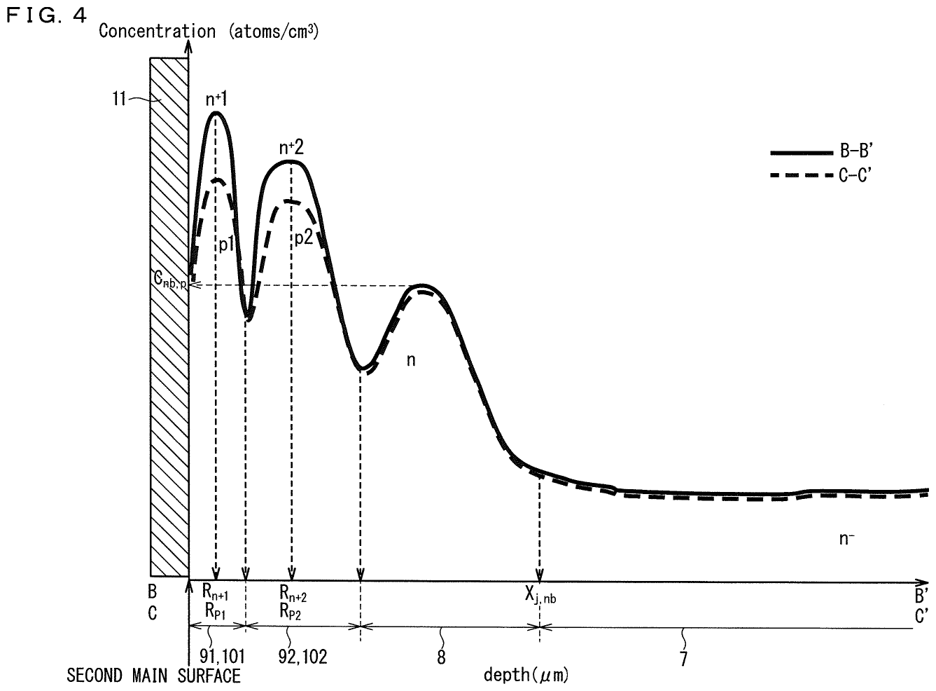

FIG. 4 illustrates impurity concentration in a diffusion layer of the RFC diode 1001 along lines B-B′ and C-C′ of FIG. 3. In FIG. 4, the horizontal axis represents a depth (μm) from the second main surface 22 of the semiconductor substrate 20, and the vertical axis represents impurity concentration (atoms/cm³). In FIG. 4, a solid line indicates impurity concentration along line B-B′, and a broken line indicates impurity concentration along line C-C′.

<A-2. Performance>

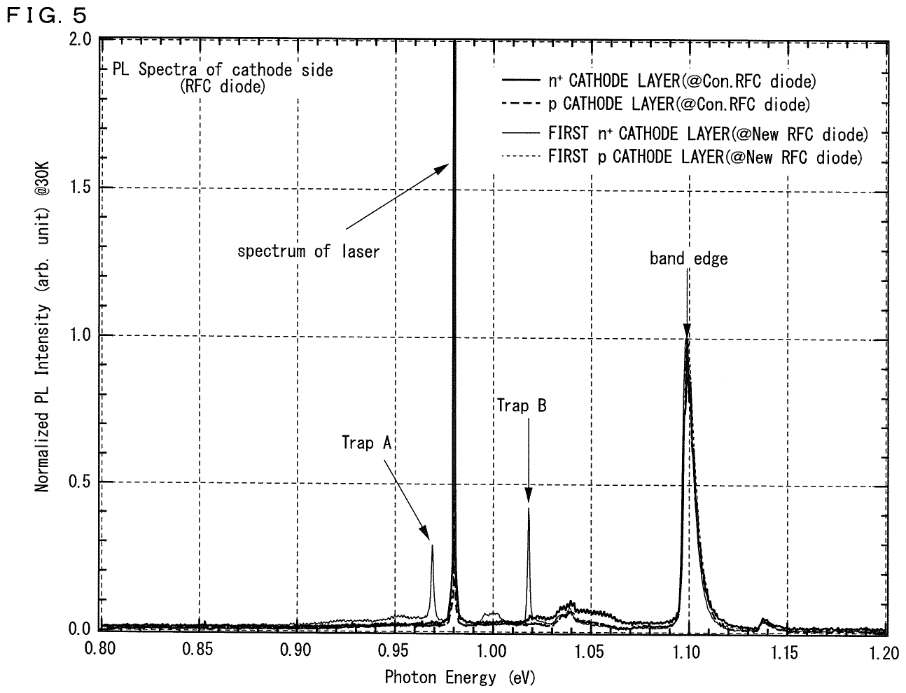

Hereinafter, performance of the RFC diode 1001 according to the first preferred embodiment will be described. FIG. 5 illustrates PL spectra when the n+ cathode layer 9 and the p cathode layer 10 in the conventional RFC diode 1000 and the first n+ cathode layer 91, the second n+ cathode layer 92, the first p cathode layer 101, and the second p cathode layer 102 in the RFC diode 1001 according to the first preferred embodiment are analyzed by a photoluminescence (PL) method. The PL method is an analysis method of irradiating a semiconductor with light and observing light emitted when electrons and holes are recombined via a defect level. The horizontal axis of FIG. 5 represents photon energy (eV), and the vertical axis of FIG. 5 represents PL intensity normalized by intensity of a band edge.

An analysis condition of the PL method is as described below. A He—Ne laser with a wavelength of 633 nm is used. Temperature is 30 K. Output of a laser beam with which a sample surface is irradiated is set to 4.5 mW. A diameter of the laser beam is 1.3 μm. Intensity of the laser beam on the sample surface is 0.339 MW/cm².

FIG. 5 shows that there are two peaks in PL intensity in the 1 n+ cathode layer 91. A first peak is due to a trap A with photon energy of 0.969 eV, and a second peak is due to a trap B with photon energy of 1.018 eV. The traps A and B are energy levels derived from CiCs (G-center) and W-center, respectively. The trap A is also referred to as a first lattice defect, and the trap B is also referred to as a second lattice defect.

As described above, there are two traps in the first n+ cathode layer 91. The second n+ cathode layer 92 is formed by a process described in a fourth preferred embodiment described later. The traps A and B, which are crystal defects in the first n+ cathode layer 91, are formed by reacting with impurities in Si such as oxygen, carbon, or hydrogen by steps below.

Step A: Ion implantation is performed on the second main surface 22 of the semiconductor substrate 20 to form a lattice defect such as an interstitial Si pair (Iₛᵢ) and a vacancy (V).

Step B: The lattice defect formed in Step A is diffused and self-aggregation occurs, and V₂ and an interstitial Si pair (Iₛⱼ: W-center) are formed.

Step C: At the same time as Step B, a substitution reaction of a carbon atom (Cₛ) present at a lattice position and an interstitial Si pair (Iₛᵢ) occurs to form an interstitial carbon (Cᵢ).

Step D: Diffusion of the interstitial carbon (Cᵢ) and the lattice defect (vacancy (V)) causes a reaction of the substitutional carbon (Cₛ) and the interstitial Si pair (Iₛᵢ) with impurities (oxygen, carbon, and hydrogen) in Si at room temperature, and an impurity defect (composite defect: CᵢCₛ) is generated.

Step E: Crystallinity is restored by annealing treatment, but some interstitial Si pairs (Iₛᵢ: W-center) and impurity defects (composite defects: CᵢCₛ) remain.

Here, the subscript i represents interstitial, and the subscript s represents substitutional.

As described above, a crystal defect exists in the first n+ cathode layer 91. The fact that diode performance of RFC diode 1001 is improved and thermally stable performance is obtained by the crystal defect will be described below by diode performance of the 1200 V class.

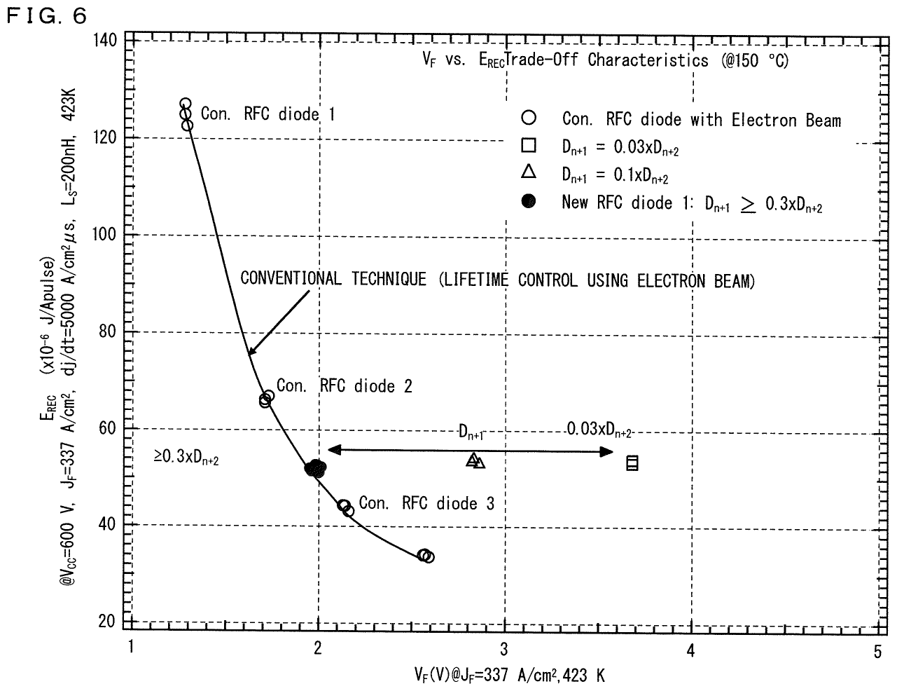

FIG. 6 illustrates a trade-off characteristic between on-voltage V_{F} and switching loss E_{REC} for each of the conventional RFC diode 1000 and the RFC diode 1001 according to the first preferred embodiment. In the trade-off characteristic of the RFC diode 1001, a relationship between a dose amount of the first n+ cathode layer 91 and a dose amount of the second n+ cathode layer 92 is shown as a parameter. The trade-off characteristic of the RFC diode 1000 is a result of control by lifetime control using an electron beam which is a charged particle. Con. RFC diode 1 in the diagram is the RFC diode 1000 without lifetime control by electron beam irradiation. Both Con. RFC diode 2 and Con. RFC diode 3 are the RFC diodes 1000 for which lifetime control by electron beam irradiation is performed, but an amount of irradiation at the time of electron beam irradiation is larger in Con. RFC diode 3 than in Con. RFC diode 2.

In the RFC diode 1001, each layer is formed by a process described in the fourth preferred embodiment such that a relationship between a dose amount of the first n+ cathode layer 91 and a dose amount of the second n+ cathode layer 92 satisfies Equation (2) below, so that contact property between the first n+ cathode layer 91 and the second metal layer 11 is improved, and stable electron injection from the first n+ cathode layer 91 is realized when the RFC diode 1001 is in an on state.

Dₙ₊₁≥0.3×Dₙ₊₂ (2)

Here, Dₙ₊₁ represents the number of atoms (atoms/cm²) per unit area of the first n+ cathode layer 91, and Dₙ₊₂ represents the number of atoms (atoms/cm²) per unit area of the second n+ cathode layer 92. The number of atoms per unit area (atoms/cm²) is a value obtained by integrating the number of atoms per unit volume (atoms/cm³) in a region of a diffusion layer in a depth direction. The number of atoms per unit volume (atoms/cm³) is an analysis value by secondary ion mass spectrometry (SIMS).

Further, in order for the RFC diode 1001 to perform normal on operation, the first n+ cathode layer 91 and the second p cathode layer 102 need to satisfy Equation (3) below with respect to a dose amount. A trade-off characteristic of the RFC diode 1001 illustrated in FIG. 6 is a result in a cathode structure that satisfies Equation (3). As described above, according to the RFC diode 1001, the high-speed side of a curve of a trade-off characteristic realized by the conventional RFC diode 1000 by lifetime control using an electron beam can be realized without the lifetime control.

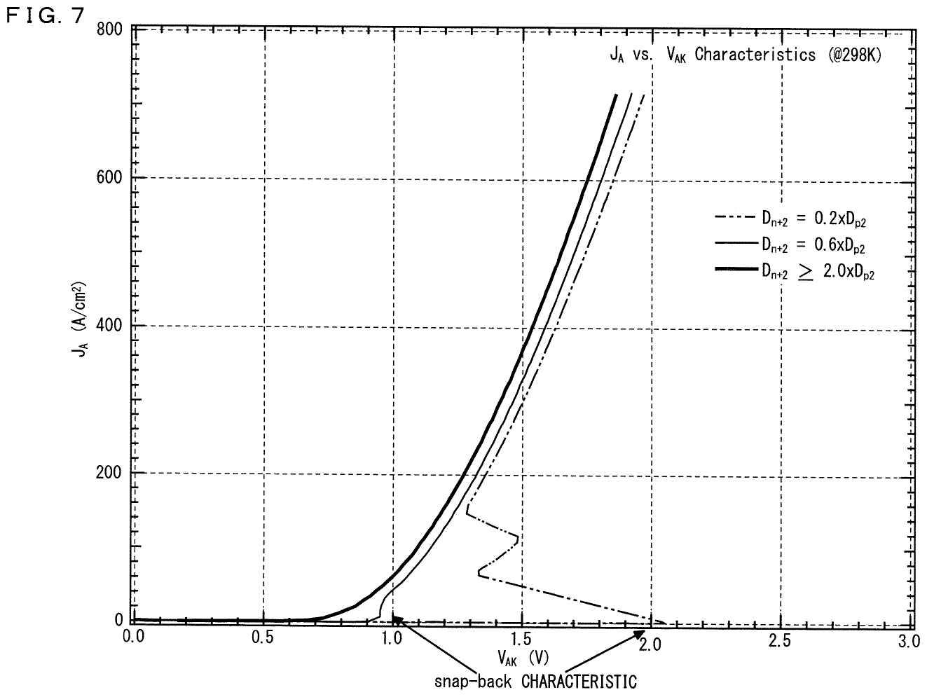

FIG. 7 illustrates an output characteristic of the RFC diode 1001 at 298 K. In the RFC diode 1001, from a relationship between a characteristic cathode structure illustrated in FIG. 3 and a process illustrated in the fourth preferred embodiment, it is necessary to invert the first p cathode layer 101 and the second p cathode layer 102 to n layers to form the first n+ cathode layer 91 and the second n+ cathode layer 92. For this reason, in order for the RFC diode 1001 to normally perform on operation, the first n+ cathode layer 91 and the second p cathode layer 102 need to satisfy Equation (3) below with respect to a dose amount. By the above, as illustrated in FIG. 7, normal on operation is guaranteed without generation of a snap-back characteristic.

Dₙ₊₂≥2.0×Dₚ₂ (3)

Here, Dₙ₊₂ represents the number of atoms (atoms/cm²) per unit area of the second n+ cathode layer 92, and Dₚ₂ represents the number of atoms (atoms/cm²) per unit area of the second p cathode layer 102.

Next, diode performance of the RFC diode 1001 satisfying Equations (2) and (3) will be described.

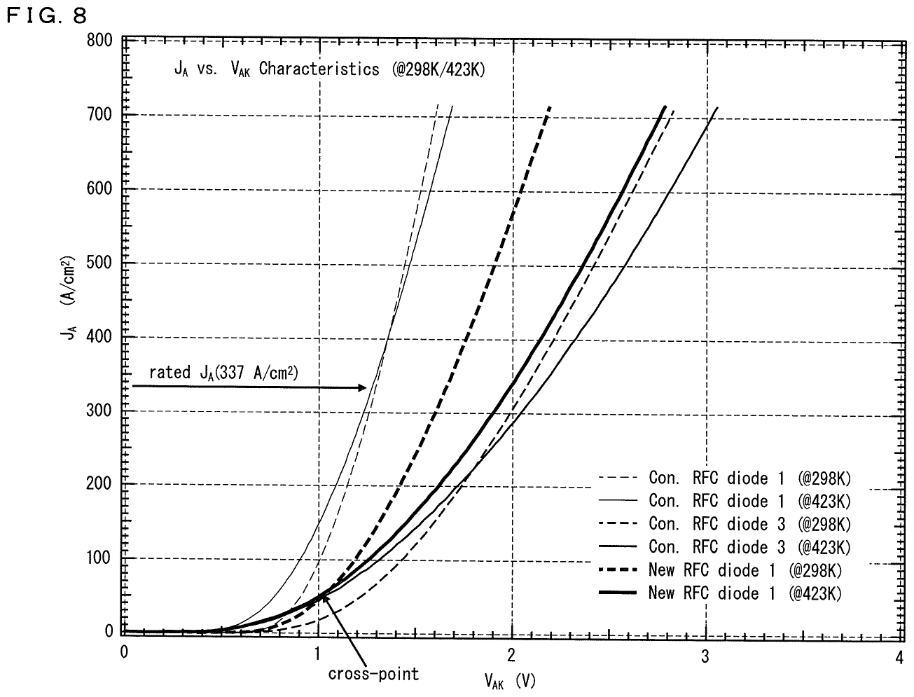

FIG. 8 illustrates an output characteristic of the conventional RFC diode 1000 and the RFC diode 1001 according to the first preferred embodiment. In FIG. 8 and diagrams that follow, the RFC diode 1000 without lifetime control by an electron beam is denoted as Con. RFC diode 1, and the RFC diode 1000 with lifetime control by an electron beam is denoted as Con. RFC diode 2 or Con. RFC diode 3.

FIG. 8 shows that the RFC diode 1001 has lower current density at a cross-point where an output characteristic at 298 K and an output characteristic at 423 K cross each other than that of the conventional RFC diode 1000.

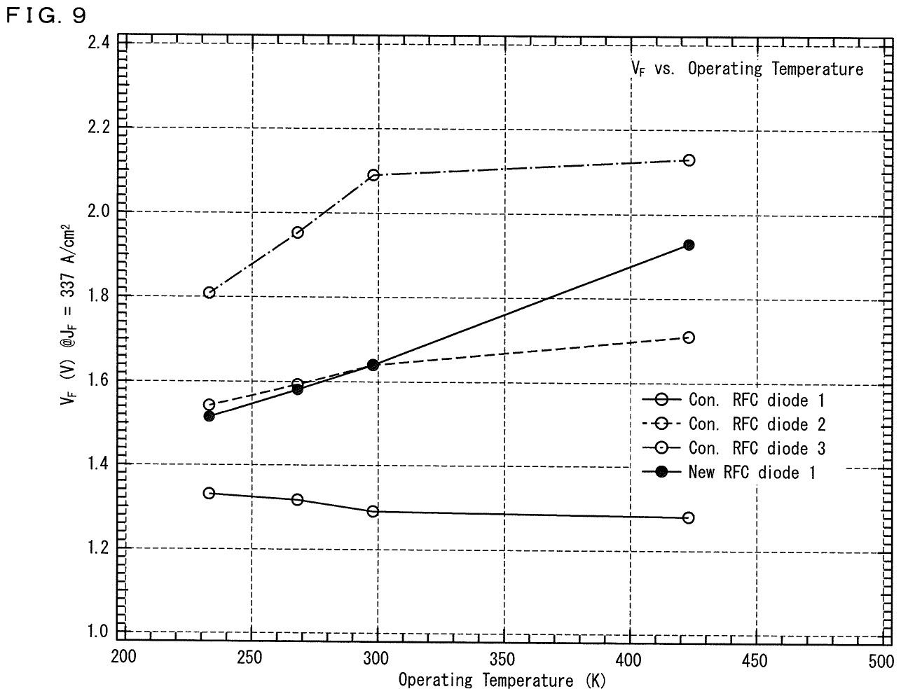

FIG. 9 illustrates operation temperature dependency of the on-voltage V_{F} of the conventional RFC diode 1000 and the RFC diode 1001 according to the first preferred embodiment. The RFC diode 1001 has positive operation temperature dependency of the on-voltage V_{F} as compared with the conventional RFC diode 1000. The conventional RFC diode 1000 without lifetime control by an electron beam is denoted as Con. RFC diode 1 in FIG. 9. In the conventional RFC diode 1000 without lifetime control by an electron beam, operation temperature dependency of the on-voltage V_{F} is negative. As shown by Con. RFC diode 3, when lifetime control by an electron beam is performed on the conventional RFC diode 1000, operation temperature dependency of the on-voltage V_{F} changes, but behavior is limited by temperature dependency of an impurity defect generated by the electron beam. Here, a main impurity defect generated by the electron beam is a composite defect CᵢOᵢ or C-center having photon energy of 0.789 eV.

Since a power semiconductor device such as an RFC diode is finally mounted on a power module and incorporated into an inverter system, parallel operation needs to be guaranteed. In order to minimize a temperature difference between chips when a large number of chips perform parallel operation, current density of the cross-point is desirably low and operation temperature dependency of the on-voltage V_{F} is desirably positive. When operation temperature dependency of the on-voltage V_{F} is negative during parallel operation of a large number of chips, a phenomenon of breakdown due to current concentration in a specific chip is likely to be induced. However, when operation temperature dependency of the on-voltage V_{F} is positive as in the RFC diode 1001, breakdown due to current concentration in a specific chip is suppressed, and normal parallel operation can be guaranteed. That is, the characteristic of the RFC diode 1001 illustrated in FIGS. 8 and 9 is effective from the viewpoint of normal operation of a power module.

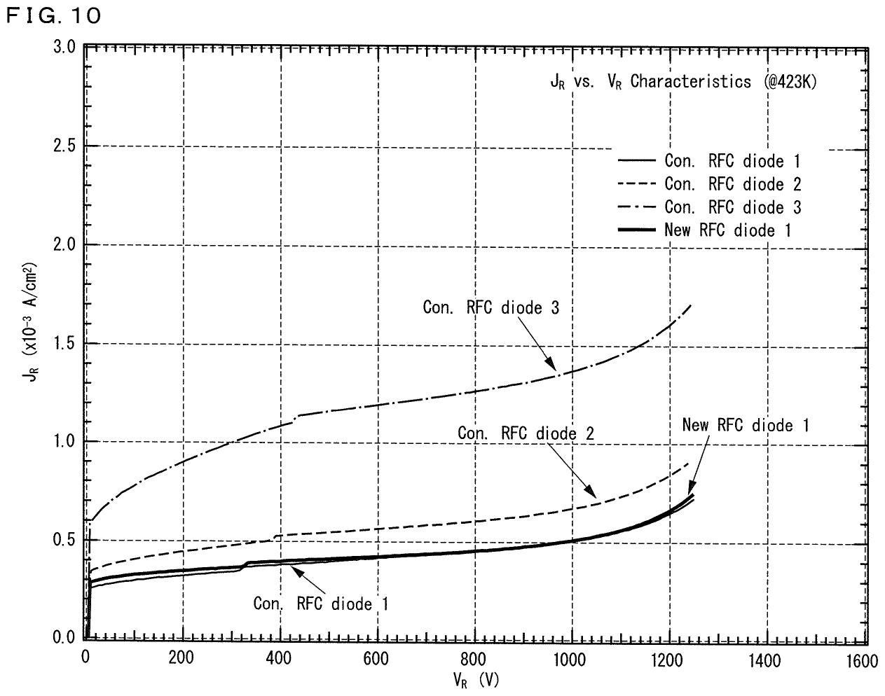

FIG. 10 illustrates a leakage characteristic when a reverse bias is applied to a main junction of the conventional RFC diode 1000 and the RFC diode 1001 according to the first preferred embodiment. In FIG. 10, the horizontal axis represents the reverse voltage V_{R}(V), and the vertical axis represents leakage current density J_{R} (A/cm²).

In the conventional RFC diode 1000, lifetime control using an electron beam is performed in order to control performance to the high-speed side on a trade-off curve in FIG. 6. At that time, since an impurity defect (composite defect) is formed inside a device by the electron beam, leakage current caused by the defect increases. As a result, loss (off-loss: J_{R}×V_{R}) when the device holds voltage increases, and a problem occurs in terms of thermal design of a power module or a problem occurs in high-temperature operation.

On the other hand, although the RFC diode 1001 according to the first preferred embodiment includes the first n+ cathode layer 91 having high crystal defect density in order to control performance to the high-speed side on a trade-off curve, there is no impurity defect (composite defect) caused by an electron beam in the n− drift layer 7 and the n buffer layer 8 in which a depletion layer extends from a main junction for voltage holding when a reverse bias is applied to the main junction. Therefore, as illustrated in FIG. 10, leakage current of the RFC diode 1001 is equivalent to leakage current of the conventional RFC diode 1000 in which lifetime control by an electron beam is not performed. That is, the RFC diode 1001 according to the first preferred embodiment has leakage current smaller than that of the conventional RFC diode 1000 while achieving high-speed operation, and is effective in terms of high-temperature operation and thermal stability.

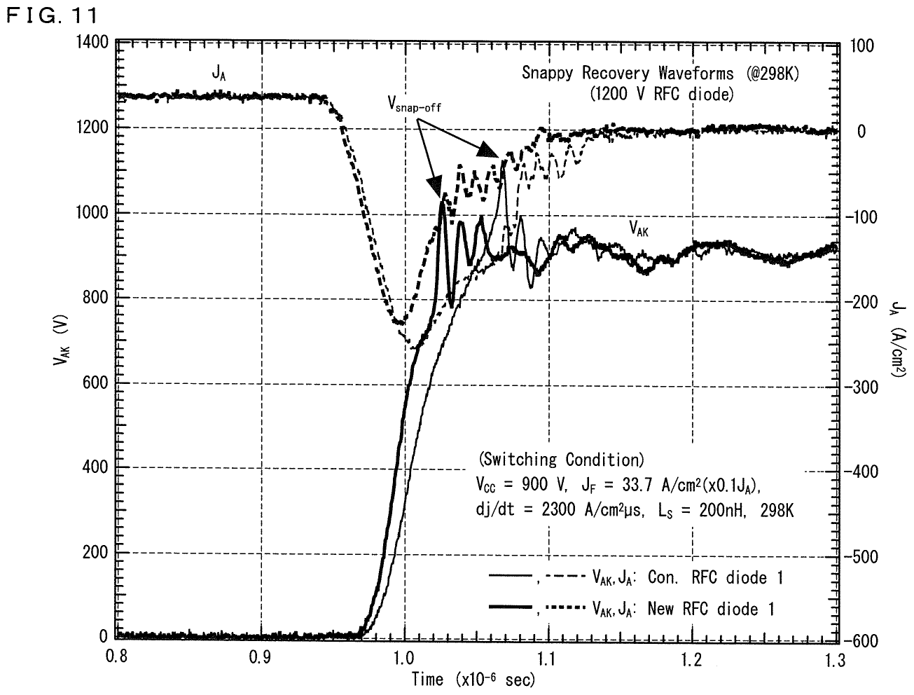

FIG. 11 illustrates waveforms of the conventional RFC diode 1000 and the RFC diode 1001 according to the first preferred embodiment during recovery operation in a small current mode.

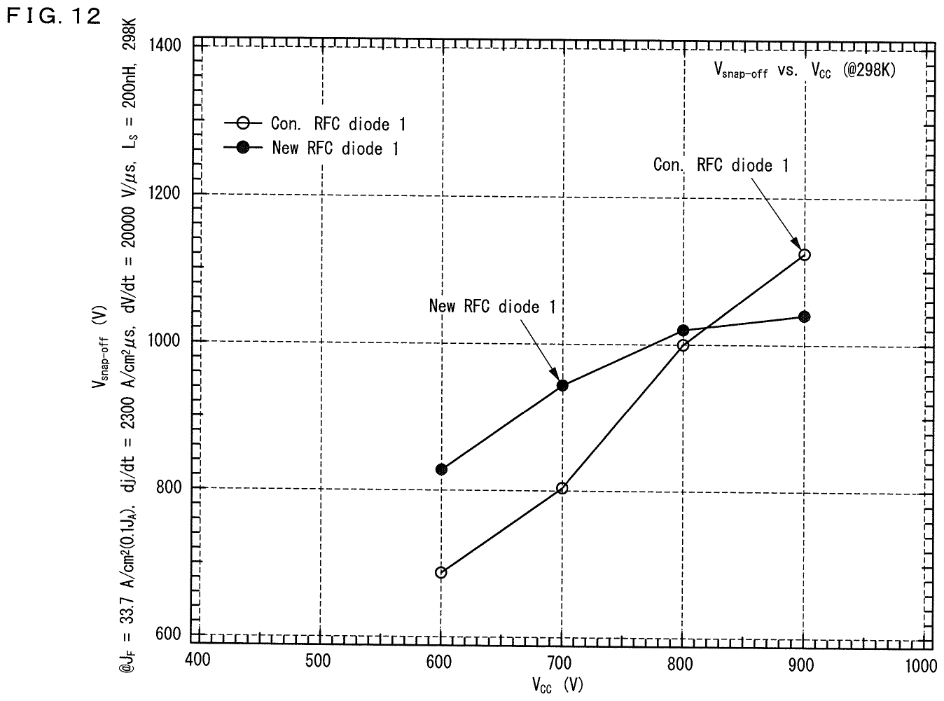

FIG. 12 is a diagram illustrating a relationship between the snap-off voltage V_{snap-off} and power supply voltage V_{CC} for the conventional RFC diode 1000 and the RFC diode 1001 according to the first preferred embodiment. The snap-off voltage V_{snap-off} is a maximum value of anode-cathode voltage V_{AK} during recovery operation. Recovery operation of a diode is excellent in terms of the breakdown tolerance of a diode when the snap-off voltage V_{snap-off} is small and the power supply voltage V_{CC} dependency of the snap-off voltage V_{snap-off} is insensitive. Further, by setting the snap-off voltage V_{snap-off} to rated withstand voltage or less, the snap-off voltage V_{snap-off} can be controlled to the rated withstand voltage or less, and it is possible to suppress diode breakdown caused by voltage instantaneously rising to the rated withstand voltage or more during recovery operation. In the present preferred embodiment, rating of the RFC diode 1001 is 1200 V.

Since this performance is remarkably exhibited in a sample without lifetime control by an electron beam, the conventional RFC diode 1000 compared in FIGS. 11 and 12 does not have lifetime control by an electron beam. These diagrams show that the RFC diode 1001 is superior to the conventional RFC diode 1000 in terms of breakdown resistance.

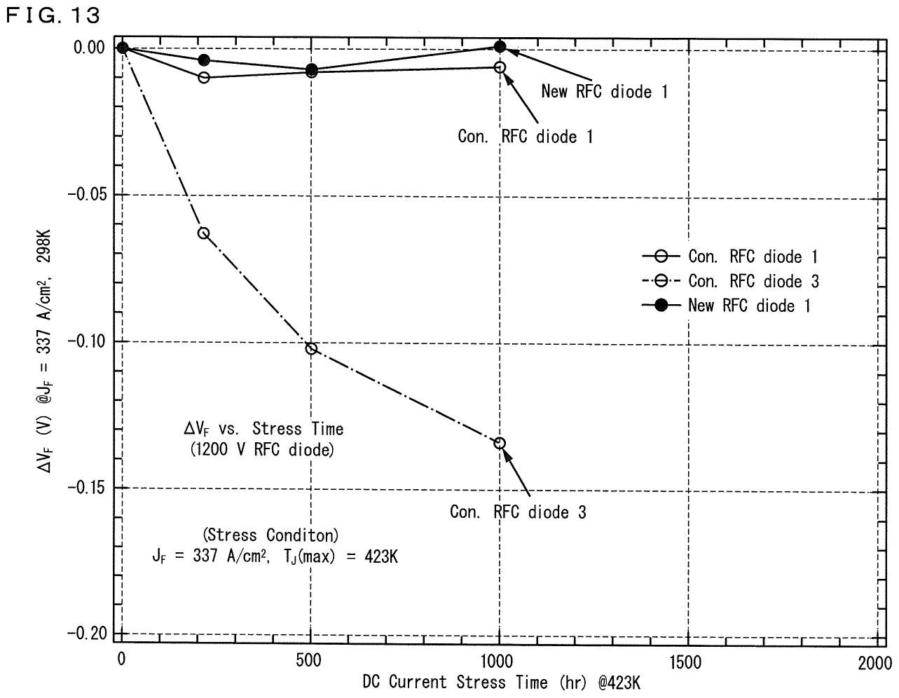

FIG. 13 illustrates changes in the on-voltage V_{F} during continuous energization test for the conventional RFC diode 1000 and the RFC diode 1001 according to the first preferred embodiment. In the conventional RFC diode 1000 (Con. RFC diode 3) in which lifetime control by an electron beam is performed, an impurity defect (composite defect) generated by the electron beam is recovered by self-heating during energization of the diode, and the on-voltage V_{F} decreases during the continuous energization test. On the other hand, in the RFC diode 1001 according to the first preferred embodiment, in addition to the fact that lifetime control by an electron beam is not performed, the traps A and B, which are crystal defects in the first n+ cathode layer 91, are thermally stable traps and do not change due to self-heating during energization of the diode. Therefore, the on-voltage V_{F} does not decrease during the continuous energization test, and diode performance does not change with time.

As described above, the RFC diode 1001 according to the first preferred embodiment utilizes the traps A and B, which are crystal defects in the first n+ cathode layer 91, to control a trade-off characteristic between the on-voltage V_{F} and the switching loss E_{REC} to the high-speed side regardless of a conventional lifetime control method, and also to achieve low off-loss, improved breakdown resistance, and thermal stability.

The performance of the RFC diode 1001 can be realized not only in a case where a Si wafer manufactured by a floating zone (FZ) method is used for the semiconductor substrate 20 but also in a case where a Si wafer manufactured by a magnetic applied Czochralski (MCZ) method having higher oxygen concentration and carbon concentration in a Si material is used. A Si wafer manufactured by the MCZ method has oxygen concentration of about 1.0×10¹⁷ atoms/cm³ or more and 7.0×10¹⁷ atoms/cm³ or less, and carbon concentration of about 1.0×10¹⁴ atoms/cm³ or more and 5.0×10¹⁵ atoms/cm³ or less. This is because a main crystal defect that controls diode performance in the RFC diode 1001 is not an impurity defect but an interstitial Si pair that is not formed by reaction with residual oxygen and residual carbon in Si.

<A-3. Effect>

The RFC diode 1001, which is the power semiconductor device according to the first preferred embodiment, includes the semiconductor substrate 20 having the first main surface 21 and the second main surface 22 facing each other, the first metal layer 5 provided on the first main surface 21 of the semiconductor substrate 20, and the second metal layer 11 provided on the second main surface 22 of the semiconductor substrate 20. The semiconductor substrate 20 includes the n− drift layer 7 which is a drift layer of a first conductivity type, then buffer layer 8 provided between the n− drift layer 7 and the second main surface 22, and a diffusion layer provided between the n buffer layer 8 and the second metal layer 11 so as to be in contact with the n buffer layer 8 and the second metal layer 11. In the RFC diode 1001, a partial region in plan view is the pin diode region 31 operating as a diode. In the RFC diode 1001, a diffusion layer includes the n+ cathode layer 90 provided in contact with the n buffer layer 8 and the second metal layer 11 in at least a part of the pin diode region 31. The n+ cathode layer 90 includes the first n+ cathode layer 91 which is a first cathode layer having one impurity concentration peak point and in contact with the second metal layer 11, and the second n+ cathode layer 92 having one impurity concentration peak point and provided between the first n+ cathode layer 91 and the n buffer layer 8 so as to be in contact with the n buffer layer 8. Crystal defect density of the first n+cathode layer 91 is higher than crystal defect density of another diffusion layer. Therefore, according to the RFC diode 1001, a trade-off characteristic between the on-voltage V_{F} and the switching loss E_{REC} is controlled to the high-speed side regardless of a conventional lifetime control method, and low off-loss, improvement in breakdown resistance, and thermal stability are realized.

### B. Second Preferred Embodiment

<B-1. Configuration>

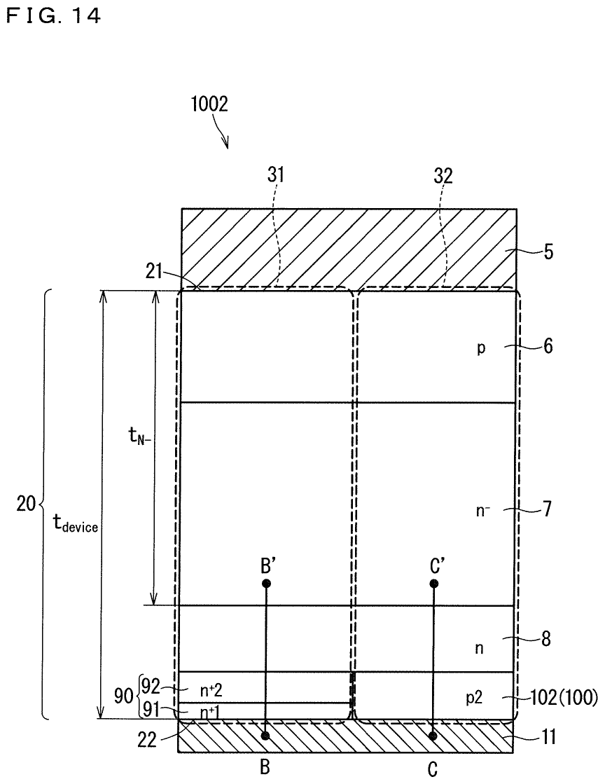

FIG. 14 illustrates a cross-sectional configuration of an RFC diode 1002 according to a second preferred embodiment taken along line A1-A1′ in FIG. 1. In a diagram below, the RFC diode 1002 according to the second preferred embodiment may be referred to as a New RFC diode 2. The RFC diode 1002 has a structure in which the first p cathode layer 101 is removed from the RFC diode 1001 according to the first preferred embodiment. In other words, in the RFC diode 1002, the p cathode layer 100 is the second p cathode layer 102. A structure of the RFC diode 1002 not specifically mentioned below is similar to that of the RFC diode 1001 according to the first preferred embodiment.

The n− drift layer 7 in the RFC diode 1002 is formed using a Si wafer having the impurity concentration Cₙ₋ of 1.0×10¹² atoms/cm³ or more and 1.0×10¹⁵ atoms/cm³ or less.

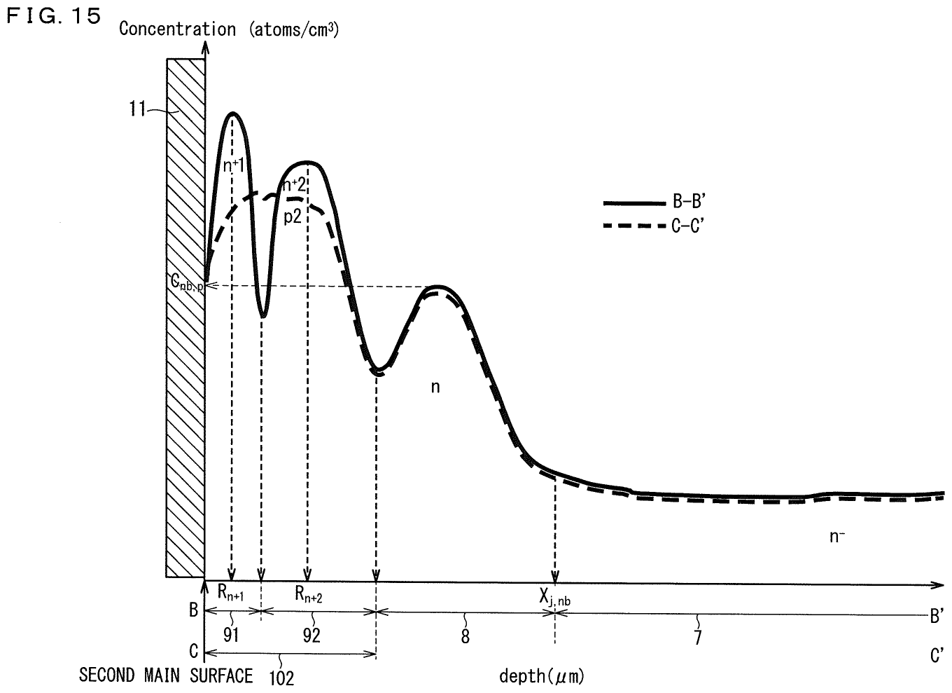

FIG. 15 illustrates impurity concentration in a diffusion layer of the RFC diode 1002 along lines B-B′ and C-C′ in FIG. 14. In FIG. 15, the horizontal axis represents a depth (μm) from the second main surface 22 of the semiconductor substrate 20, and the vertical axis represents impurity concentration (atoms/cm³). In FIG. 15, a solid line indicates impurity concentration along line B-B′, and a broken line indicates impurity concentration along line C-C′.

A parameter of each diffusion layer constituting the RFC diode 1002 are as described below.

The p anode layer 6, the n buffer layer 8, the first n+ cathode layer 91, and the second n+ cathode layer 92 are the same as those in the first preferred embodiment.

The second p cathode layer 102 has impurity concentration of 1.0×10¹⁷ atoms/cm³ or more and 1.0×10¹⁹ atoms/cm³ or less on a surface in contact with the second metal layer 11, that is, on the second main surface 22, and has a depth of 0.3 μm or more and 0.5 μm or less.

A relationship between a dose amount of the first n+ cathode layer 91 and a dose amount of the second n+ cathode layer 92 satisfies Equation (2).

<B-2. Performance>

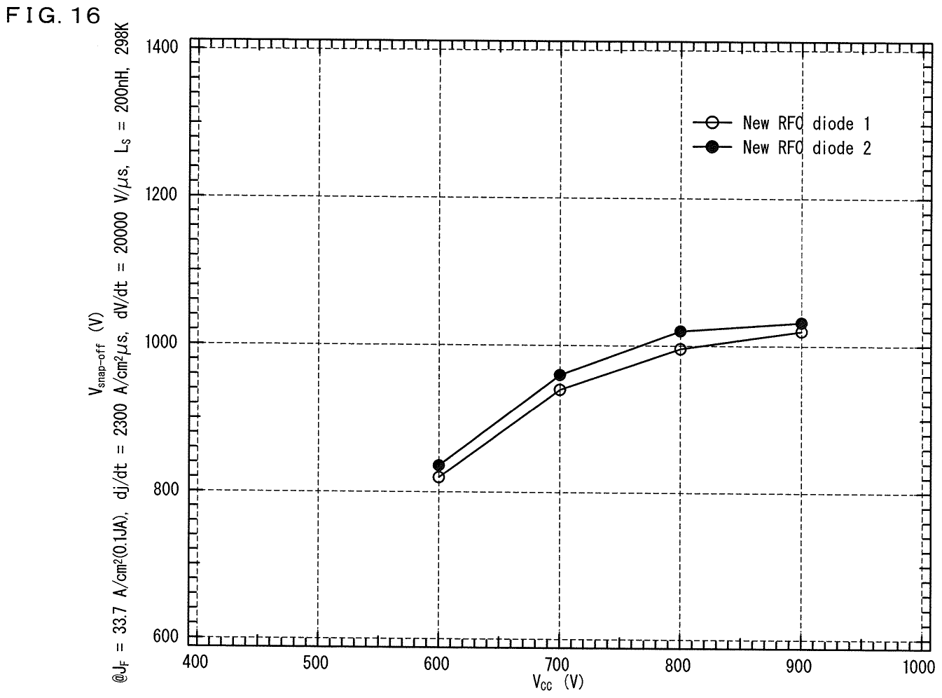

FIG. 16 illustrates a relationship between V_{snap-off} and the power supply voltage V_{CC} during the recovery operation in the small current mode of the RFC diode 1001 according to the first preferred embodiment and the RFC diode 1002 according to the second embodiment.

As can be seen from FIG. 16, in the RFC diode 1002, similarly to the RFC diode 1001 according to the first preferred embodiment, performance in terms of breakdown resistance is guaranteed.

Further, since the RFC diode 1002 includes the same n+ cathode layer 90 as the RFC diode 1001 according to the first preferred embodiment, similarly to the RFC diode 1001, the trade-off characteristic between the on-voltage V_{F} and the switching loss E_{REC} is controlled to the high-speed side regardless of a conventional lifetime control method, and low off-loss and thermal stability are realized.

<B-3. Effect>

In the RFC diode 1002 according to the second preferred embodiment, the p cathode layer 100 is the second p cathode layer 102. That is, in the RFC diode 1002, the p cathode layer 100 which is a diffusion layer of a second conductivity type has one impurity concentration peak point. Even in such a configuration, the RFC diode 1002 controls the trade-off characteristic between the on-voltage V_{F} and the switching loss E_{REC} to the high-speed side regardless of a conventional lifetime control method by the characteristic first n+ cathode layer 91, and realizes low off-loss, improvement in breakdown resistance, and thermal stability.

### C. Third Preferred Embodiment

<C-1. Configuration>

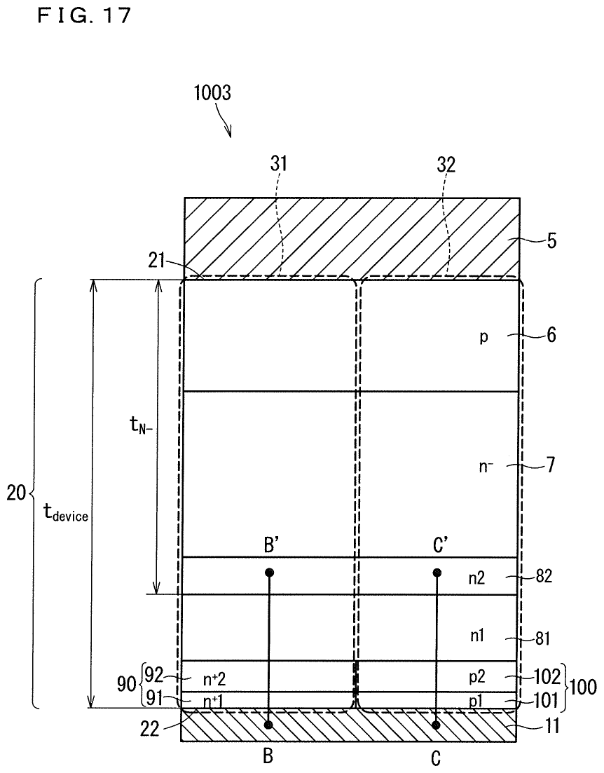

FIG. 17 illustrates a cross-sectional configuration of an RFC diode 1003 according to a third preferred embodiment taken along line A1-A1′ in FIG. 1. In a diagram below, the RFC diode 1003 according to the third preferred embodiment may be referred to as a New RFC diode 3. The RFC diode 1003 is different from the RFC diode 1001 according to the first preferred embodiment in including an n buffer layer 80 instead of the n buffer layer 8. The n buffer layer 80 has a two-layer structure including a first n buffer layer 81 and a second n buffer layer 82. A structure of the RFC diode 1003 not specifically mentioned below is similar to that of the RFC diode 1001 according to the first preferred embodiment.

The n− drift layer 7 in the RFC diode 1003 is formed using a Si wafer having the impurity concentration Cₙ₋ of 1.0×10¹² atoms/cm³ or more and 1.0×10¹⁵ atoms/cm³ or less.

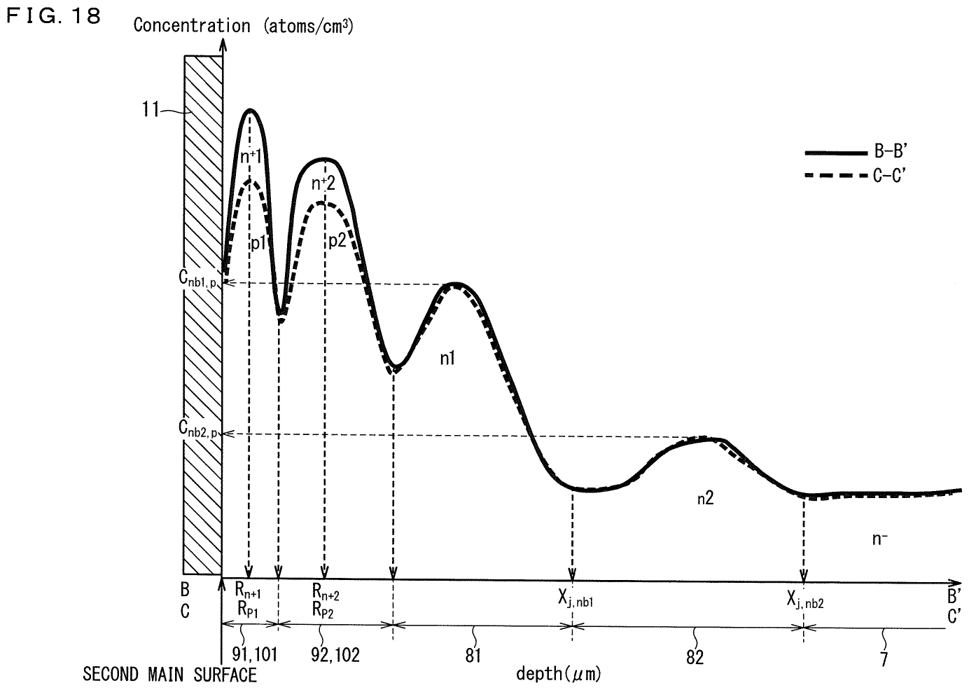

FIG. 18 illustrates impurity concentration in a diffusion layer of the RFC diode 1003 along lines B-B′ and C-C′ in FIG. 17. In FIG. 18, the horizontal axis represents a depth (μm) from the second main surface 22 of the semiconductor substrate 20, and the vertical axis represents impurity concentration (atoms/cm³). In FIG. 18, a solid line indicates impurity concentration along line B-B′, and a broken line indicates impurity concentration along line C-C′.

The p anode layer 6 is similar to that of the first preferred embodiment.

In the first n buffer layer 81, peak impurity concentration C_{nb1, p} is 1.0×10¹⁵ atoms/cm³ or more and 5.0×10¹⁶ atoms/cm³ or less, and the depth X_{j, nb1} is 1.2 μm or more and 50 μm or less.

The second n buffer layer 82 has a depth X_{j, nb2} of X_{j, nb1}+20 μm. Further, peak impurity concentration C_{nb2, p} of the second n buffer layer 82 is 0.01 times or less peak impurity concentration C_{nb1, p} of the first n buffer layer 81. By the above, occurrence of a snap-back characteristic in the on state as illustrated in FIG. 7 is suppressed, and normal on operation of a diode is guaranteed.

<C-2. Performance>

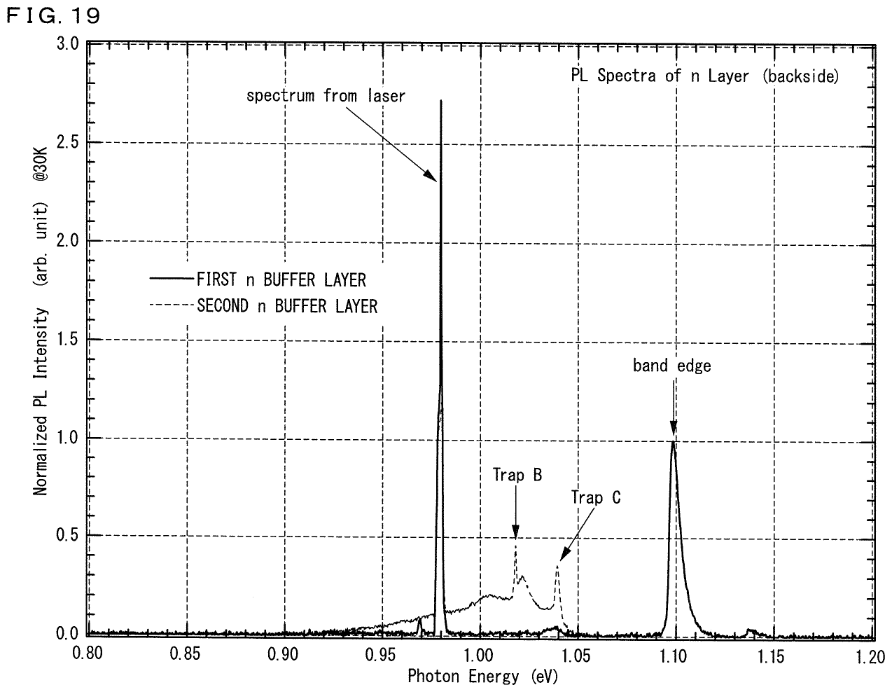

FIG. 19 illustrates PL spectra when the first n buffer layer 81 and the second n buffer layer 82 of the RFC diode 1003 are analyzed by the PL method. The horizontal axis of FIG. 19 represents photon energy (eV), and the vertical axis of FIG. 19 represents PL intensity normalized by intensity of a band edge.

An analysis condition of the PL method in FIG. 19 is similar to the analysis condition of the PL method in FIG. 5. It can be seen from FIG. 19 that there are two peaks in the PL intensity in the second n buffer layer 82. A first peak is due to the trap B with photon energy of 1.018 eV, and a second peak is due to a trap C with photon energy of 1.039 eV. The traps B and C are energy levels derived from W-center and X-center, which are interstitial Si pairs.

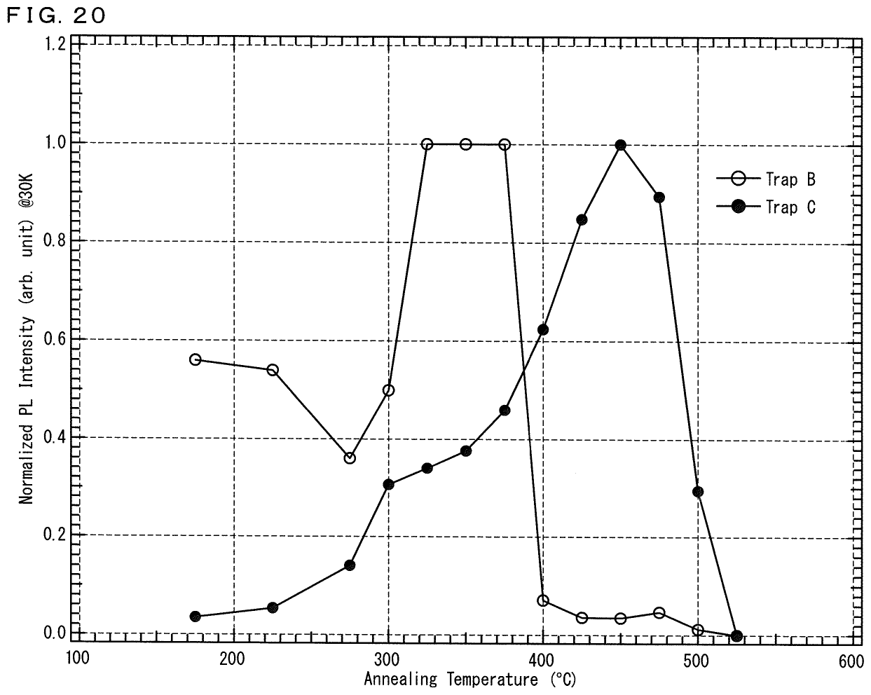

FIG. 20 illustrates a relationship between PL intensity and annealing temperature in the traps B and C in the second n buffer layer 82. Annealing is performed in nitrogen atmosphere for 120 minutes. A technique of the present preferred embodiment mainly focuses on device performance control of a power diode by the trap B. From FIG. 20, it can be seen that annealing temperature for the trap B to be a main trap in the second n buffer layer is 370° C. or less.

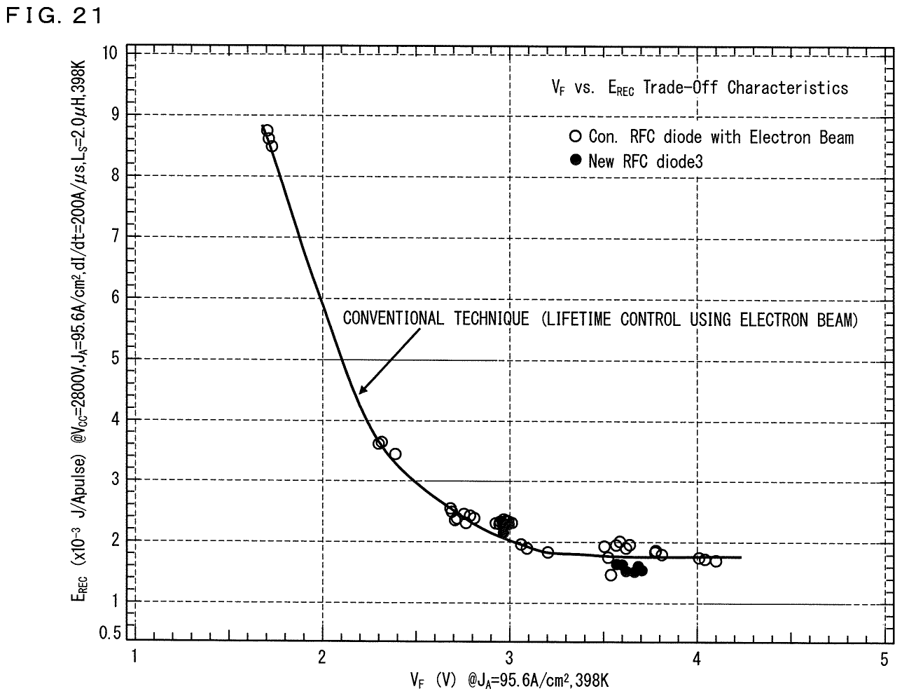

FIG. 21 illustrates a trade-off characteristic between on-voltage V_{F} and switching loss E_{REC} for each of the conventional RFC diode 1000 and the RFC diode 1003 according to the third preferred embodiment. Withstand voltage of the RFC diode having a characteristic illustrated in FIG. 21 is 4.5 kV.

By controlling a condition at the time of ion implantation when the second n buffer layer 82 is formed so that the peak impurity concentration C_{nb2, p} of the second n buffer layer 82 satisfies C_{nb2, p}≤0.01×C_{nb1, p} with the peak impurity concentration C_{nb1, p} of the first n buffer layer 81, it is possible to realize the high-speed side of the curve of the trade-off characteristic realized by the conventional RFC diode 1000 by the lifetime control using an electron beam without adversely affecting other device performance of the diode.

Further, since the RFC diode 1003 according to the third preferred embodiment controls power diode performance by utilizing an interstitial Si pair without the lifetime control, similarly to the first preferred embodiment, low off-loss, improvement in breakdown resistance, and thermal stability are realized.

<C-3. Effect>

In the RFC diode 1003 according to the third embodiment, the n buffer layer 80 includes the first n buffer layer 81 which is a first buffer layer having one impurity concentration peak point and in contact with a diffusion layer, and the second n buffer layer 82 which is a second buffer layer having one impurity concentration peak point and in contact with the n− drift layer 7. Then, a crystal defect in the second n buffer layer 82 is the trap B which is a second lattice defect and the trap C which is a third lattice defect detected by a photoluminescence method. Therefore, according to the RFC diode 1003, a trade-off characteristic between the on-voltage V_{F} and the switching loss E_{REC} is controlled to the high-speed side regardless of a conventional lifetime control method, and low off-loss, improvement in breakdown resistance, and thermal stability are realized.

### D. Fourth Preferred Embodiment

<D-1. Manufacturing Method>

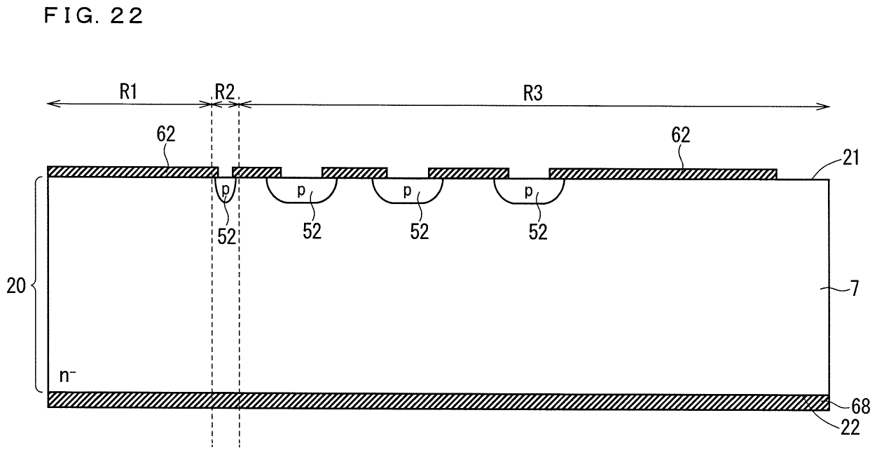

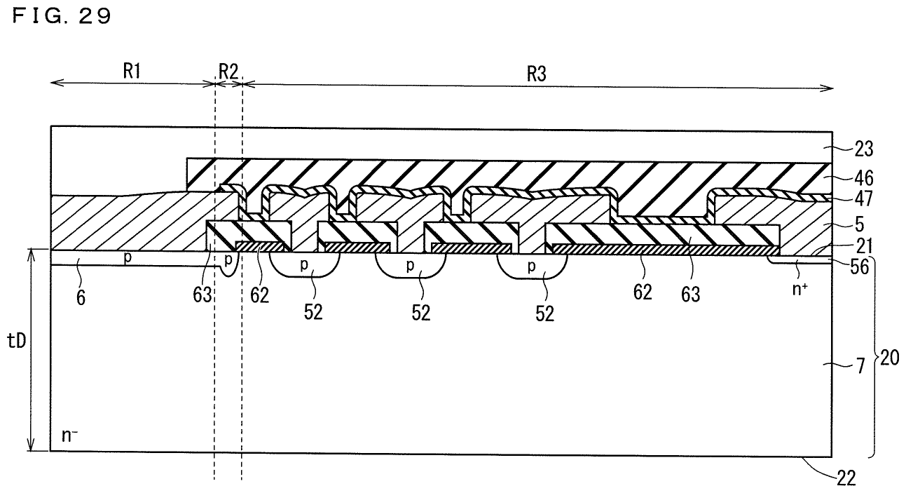

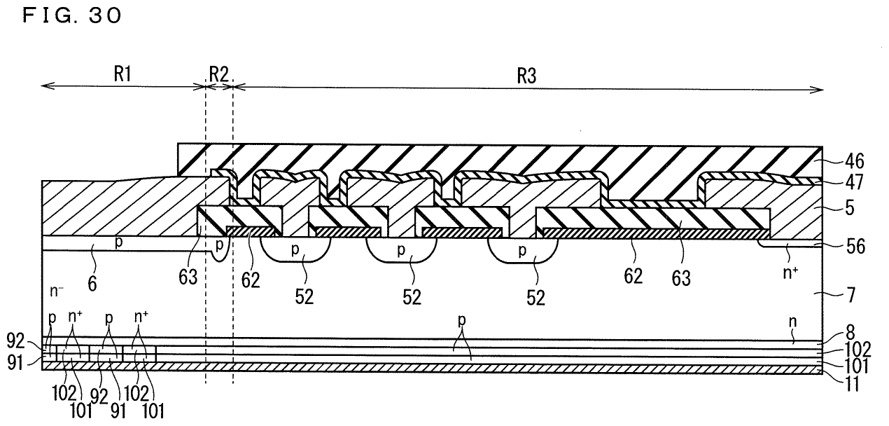

In the present preferred embodiment, a method for manufacturing the RFC diode 1001 according to the first preferred embodiment will be described. FIGS. 22 to 30 are cross-sectional views illustrating the method for manufacturing the RFC diode 1001. FIGS. 29 and 30 illustrate a detailed process for forming a back side structure of the RFC diode 1001.

A characteristic of the method for manufacturing the RFC diode 1001 is as described below. First, after ion implantation for forming the first p cathode layer 101 and the second p cathode layer 102, ion implantation for forming the first n+ cathode layer 91 and the second n+ cathode layer 92 and annealing are present. Further, there is no lifetime control process. Further, the second metal layer 11 is for a two-layer diffusion layer structure.

Hereinafter, the method for manufacturing the RFC diode 1001 will be described with reference to FIGS. 22 to 30. FIG. 22 illustrates the active cell region R1, and the intermediate region R2 and the termination region R3 formed so as to surround the active cell region R1. First, the semiconductor substrate 20 on which only the n− drift layer 7 is formed is prepared. Then, a plurality of p layers 52 are selectively formed on a surface of the n− drift layer 7 in the intermediate region R2 and the termination region R3. The p layer 52 is formed by performing ion implantation using an oxide film 62 formed in advance as a mask and then performing annealing processing on the semiconductor substrate 20. Note that an oxide film 68 at the time of formation of the oxide film 62 also formed on the second main surface 22 of the semiconductor substrate 20.

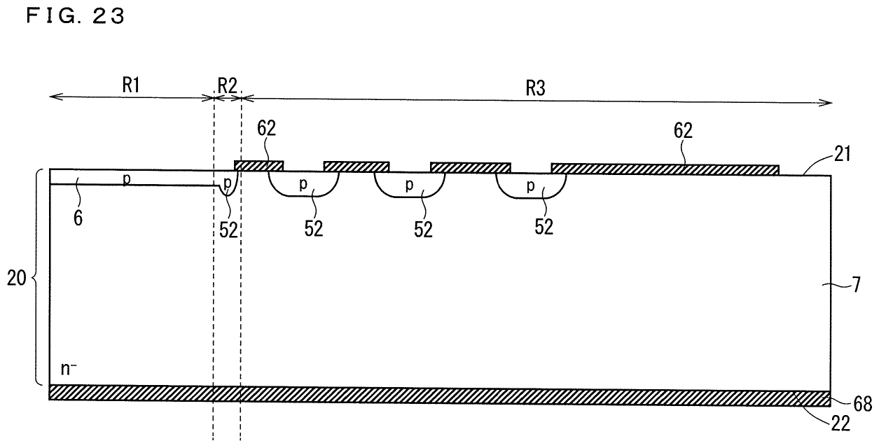

Next, as illustrated in FIG. 23, ion implantation and annealing processing are performed on a surface of the n− drift layer 7 in the active cell region R1 to form the p anode layer 6.

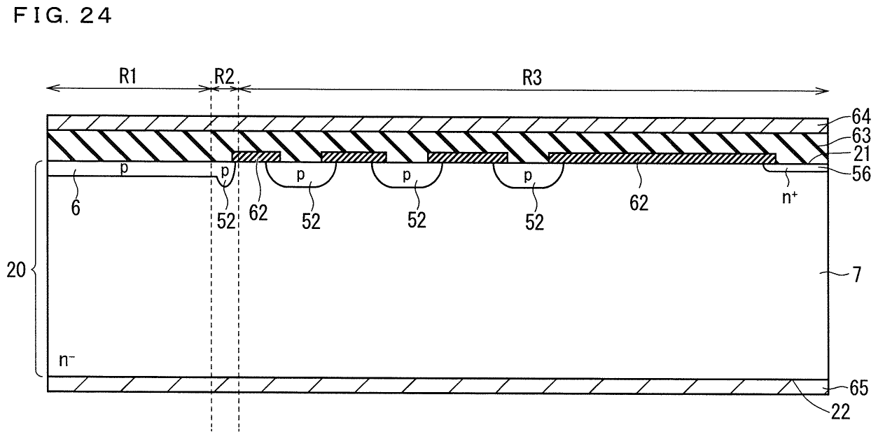

Subsequently, as illustrated in FIG. 24, an n+ layer 56 is formed in an end portion of the termination region R3 on the first main surface 21 side of the semiconductor substrate 20. Next, a TEOS layer 63 is formed on an upper surface of the semiconductor substrate. After the above, processing of removing the oxide film 68 to expose the second main surface 22 of the semiconductor substrate 20 is performed. Then, a doped polysilicon layer 65 doped with an impurity is formed so as to be in contact with the n− drift layer 7 exposed on the second main surface 22 of the semiconductor substrate 20. The impurity of the doped polysilicon layer 65 is, for example, an atom that diffuses into Si and can form an n+ layer, such as phosphorus, arsenic, or antimony. The doped polysilicon layer 65 is a film doped with high-concentration impurities of 1×10¹⁹ atoms/cm³ or more, and has film thickness of 500 nm or more. At this time, a doped polysilicon layer 64 is also formed on the first main surface 21 of the semiconductor substrate 20.

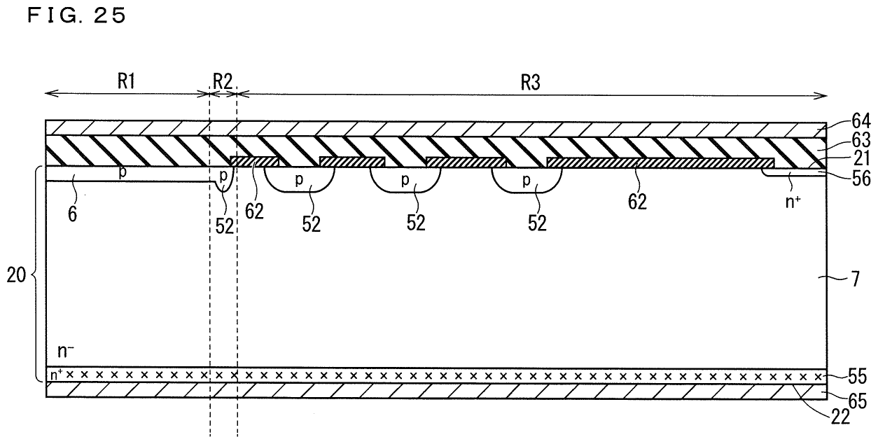

Next, the semiconductor substrate 20 is thermally annealed at 900° C. or more and 1000° C. or less in nitrogen atmosphere. Further, by setting heating temperature to 600° C. or more and 700° C. or less at an optional temperature decreasing speed in the nitrogen atmosphere and performing low-temperature thermal annealing, as illustrated in FIG. 25, impurities in the doped polysilicon layer 65 are diffused to the second main surface 22 side of the n− drift layer 7, and a gettering layer 55 having a crystal defect and an impurity is formed on the second main surface 22 side of the n− drift layer 7. After the above, an annealing process is performed to capture a metal impurity, a contaminating atom, and damage of the n− drift layer 7 by the gettering layer 55. By the above, carrier lifetime of the n− drift layer 7 decreased during the wafer process to that point is recovered, and a value equal to or more than it determined by Equation (4) is realized. The present process can also be employed in an IGBT or a reverse conductivity (RC)-IGBT in addition to an RFC diode.

τₜ=1.5×10⁻⁵exp(5.4×10³t_{N-}) (4)

Here, t_{N-} represents thickness (m) of the n− drift layer 7. τₜ represents carrier lifetime (sec) in the n− drift layer 7 in which influence of carrier lifetime on on-voltage is eliminated.

On-voltage of the RFC diode 1001 depends on carrier lifetime of the n− drift layer 7. Equation (4) represents carrier lifetime τₜ (s) that minimizes dependency of on-voltage of the RFC diode 1001 on carrier lifetime of the n− drift layer 7. If the carrier lifetime τₜ represented by Equation (4) can be realized, influence of carrier lifetime on switching loss can be minimized, and it is effective for reducing off-loss or suppressing thermal runaway.

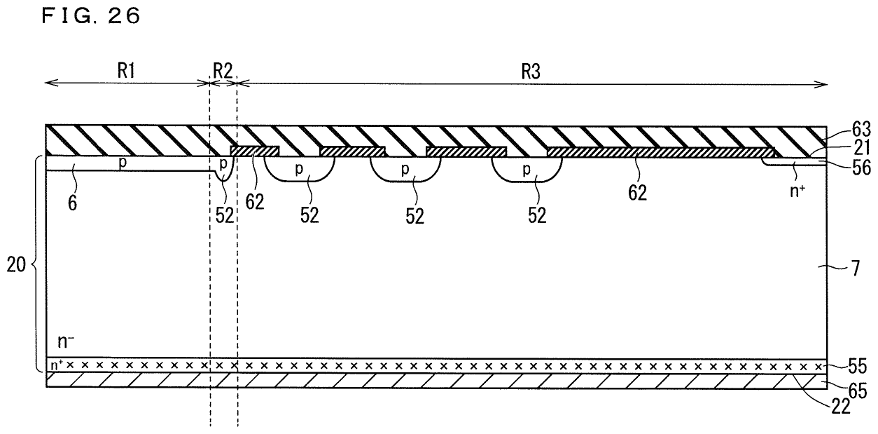

After the above, as illustrated in FIG. 26, the doped polysilicon layer 64 formed on the first main surface 21 side of the semiconductor substrate 20 is selectively removed using liquid of hydrofluoric acid or mixed acid (for example, mixed solution of hydrofluoric acid/nitric acid/acetic acid).

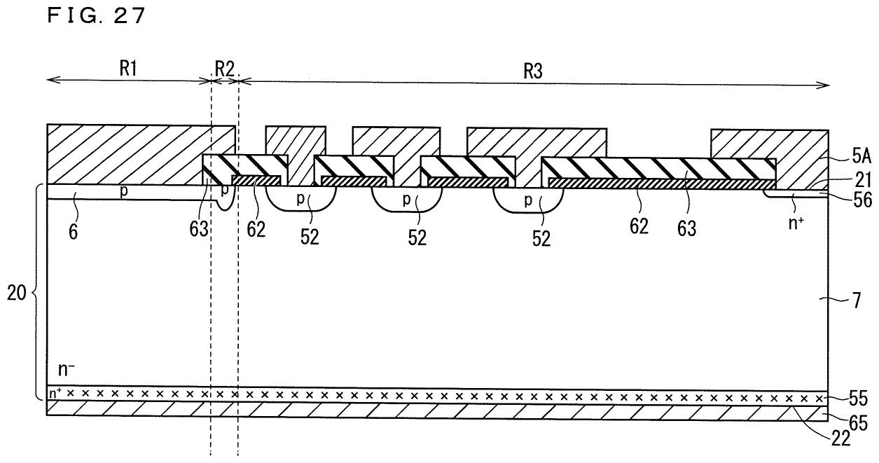

Next, as illustrated in FIG. 27, a contact hole for exposing the p layer 52, the p anode layer 6, and the n+ layer 56 is formed on the first main surface 21 of the semiconductor substrate 20. That is, the TEOS layer 63 is processed as illustrated in FIG. 27. After the above, an aluminum wiring 5A to which Si is added to about 1% or more and 3% or less is formed by a sputtering method. The aluminum wiring 5A corresponds to the first metal layer 5 in. FIG. 3.

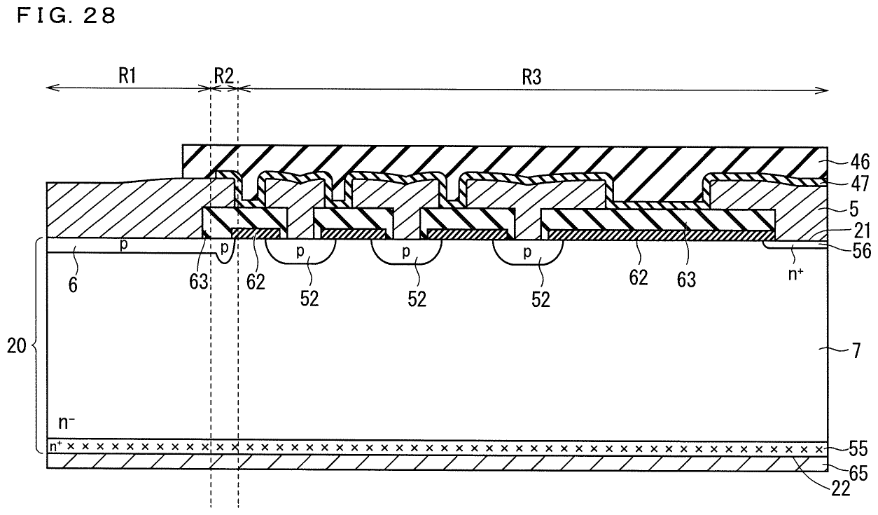

Subsequently, as illustrated in FIG. 28, passivation films 46 and 47 are formed on the first main surface 21 side of the semiconductor substrate 20.

After the above, as illustrated in FIG. 29, a surface protective film 23 is formed on the first main surface 21 side of the semiconductor substrate 20. Then, the gettering layer 55 and the doped polysilicon layer 65 formed on the second main surface 22 of the semiconductor substrate 20 are removed by polishing or etching. Through this removal process, thickness tD of the semiconductor substrate 20 corresponds to a withstand voltage class of the semiconductor device.

Then, as illustrated in FIG. 30, the n buffer layer 8 is formed on the lower surface side of the n− drift layer 7. After the above, the first p cathode layer 101 and the second p cathode layer 102 are formed on a lower surface of the n buffer layer 8. Subsequently, in the active cell region R1, a conductivity type of a part of the first p cathode layer 101 and the second p cathode layer 102 is inverted to form the first n+ cathode layer 91 and the second n+ cathode layer 92. The n buffer layer 8, the first p cathode layer 101, the second p cathode layer 102, the first n+ cathode layer 91, and the second n+ cathode layer 92 are diffusion layers formed by ion implantation and annealing.

Note that, when a diffusion layer is formed, the aluminum wiring 5A and the passivation films 46 and 47 are present on the first main surface 21 side of the semiconductor substrate 20. For this reason, annealing for forming a diffusion layer is performed using a laser having a temperature gradient in a device depth direction so that the first main surface 21 side of the semiconductor substrate 20 has temperature lower than a melting point 660° C. of aluminum used for the aluminum wiring 5A, and having a wavelength at which heat is not transmitted to the first main surface 21 side.

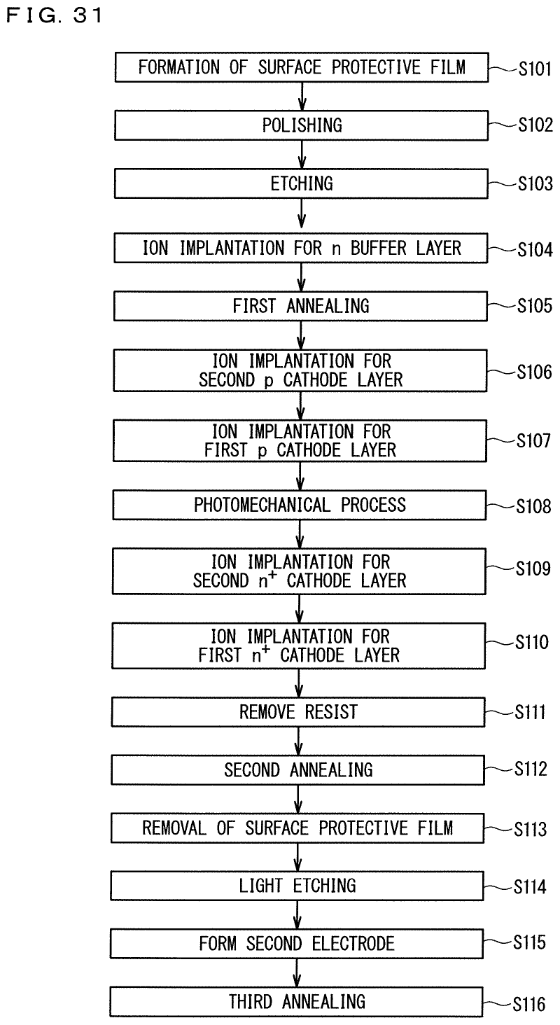

FIG. 31 is a flowchart illustrating a manufacturing process in FIGS. 29 and 30.

First, in Step S101, the surface protective film 23 is formed on the first main surface 21 side of the semiconductor substrate 20. Next, in Steps S102 and S103, the gettering layer 55 and the doped polysilicon layer 65 formed on the second main surface 22 of the semiconductor substrate 20 are removed by polishing and etching. Through this removal process, the thickness tD of the semiconductor substrate 20 corresponds to a withstand voltage class of the semiconductor device.

Next, in Step S104, ion implantation for forming the n buffer layer 8 is performed. This ion implantation is also referred to as first ion implantation. Next, in Step S105, annealing for activating an ion implanted in Step S104 is performed. The annealing in Step S105 is also referred to as first annealing.

After the above, in Step S106, ion implantation for forming the second p cathode layer 102 is performed. This ion implantation is also referred to as second ion implantation.

Next, in Step S107, ion implantation for forming the first p cathode layer 101 is performed. This ion implantation is also referred to as third ion implantation. Acceleration energy in the second ion implantation and the third ion implantation is determined so that a range satisfies Equation (1). By the above, the first p cathode layer 101 and the second p cathode layer 102 are formed so as not to interfere with each other.

Next, in Step S108, a mask for partially forming the first n+ cathode layer 91 and the second n+ cathode layer 92 is formed in the active cell region R1 by a photomechanical process.

After the above, in Step S109, ion implantation for forming the second n+ cathode layer 92 is performed. This ion implantation is also referred to as fourth ion implantation.

Subsequently, in Step S110, ion implantation for forming the first n+ cathode layer 91 is performed. This ion implantation is also referred to as fifth ion implantation. Acceleration energy in the fourth ion implantation and the fifth ion implantation is determined so that a range satisfies Equation (1). By the above, the first n+ cathode layer 91 and the second n+ cathode layer 92 are formed so as not to interfere with each other.

Next, in Step S111, a resist for the photomechanical process is removed.

After the above, in Step S112, annealing for activating the ions implanted in Steps S106, S107, S109, and S110 is performed. By this annealing, the first p cathode layer 101, the second p cathode layer 102, the first n+ cathode layer 91, and the second n+ cathode layer 92 are formed. The annealing in Step S112 is also referred to as second annealing. The first annealing and the second annealing are performed by laser annealing or in a diffusion furnace at a low temperature equal to or less than a metal melting point of the first metal layer 5. A characteristic of the annealing employed here is to reproduce an impurity profile during ion implantation even after activation after annealing.

After the above, in Step S113, the surface protective film 23 is removed. Next, in Step S114, the second main surface 22 is applied with light etching.

After the above, in Step S115, the second metal layer 11 is formed on the second main surface 22 by a sputtering method. The second metal layer 11 is a laminated film including a plurality of metal films, and is, for example, a laminated film of metal in contact with Si, Ti, Ni, and Au. By using a monosilicide layer of AlSi, NISi, or the like to which Si is added by about 1% or more and about 3% or less as a metal layer in contact with Si, an effect of the cathode layer characteristic of the RFC diode 1001 is guaranteed.

Next, annealing at 350° C. is performed in Step S116 to form an alloy layer or a silicide layer at an interface between the first p cathode layer 101 and the second metal layer 11 and between the first n+ cathode layer 91 and the second metal layer 11. The annealing in Step S116 is also referred to as third annealing.

<D-2. Effect>

According to the method for manufacturing RFC diode 1001 described in the fourth preferred embodiment, the first metal layer 5 and the surface protective film 23 are formed on the first main surface 21 of the semiconductor substrate 20 having the n− drift layer 7, thickness of the semiconductor substrate 20 is controlled to desired thickness after formation of the surface protective film 23, first ion implantation and first annealing for forming the n buffer layer 8 on the second main surface 22 of the semiconductor substrate are performed after thickness control of the semiconductor substrate 20, second ion implantation for forming the second p cathode layer 102 that is a second diffusion layer of a second conductivity type on the second main surface 22 of the semiconductor substrate is performed after the first annealing, and third ion implantation for forming the first p cathode layer 101 that is a first diffusion layer of a second conductivity type on the second main surface of the semiconductor substrate 20 is performed with acceleration energy smaller than that of the second ion implantation after the second ion implantation, fourth ion implantation for forming the second n+ cathode layer 92, which is a second cathode layer of a first conductivity type on the second main surface 22 of the semiconductor substrate 20 after the third ion implantation, fifth ion implantation for forming the first n+ cathode layer 91, which is a first cathode layer of a first conductivity type, on the second main surface 22 of the semiconductor substrate 20 is performed with acceleration energy smaller than that of the fourth ion implantation after the fourth ion implantation, second annealing for activating ions implanted by the second, third, fourth, and fifth ion implantation is performed after the fifth ion implantation so that the second p cathode layer 102, the first p cathode layer 101, the second cathode layer 92, and the first n+ cathode layer 91, the second metal layer 11 is formed on the second main surface 22 of the semiconductor substrate 20 after the second annealing, and third annealing is performed at 350° C. in nitrogen atmosphere after formation of the second metal layer 11. By the above, the first p cathode layer 101 and the second p cathode layer 102, and the first n+ cathode layer 91 and the first n+ cathode layer 92 having different roles can be formed so as to satisfy relationships of Equations (1), (2), and (3), and the trade-off characteristic between the on-voltage V_{F} and the switching loss E_{REC} is controlled to the high-speed side regardless of a conventional life time control method, and reduction of off-loss, improvement in breakdown resistance, and thermal stability are realized.

### E. Fifth Preferred Embodiment

<E-1. Manufacturing Method>

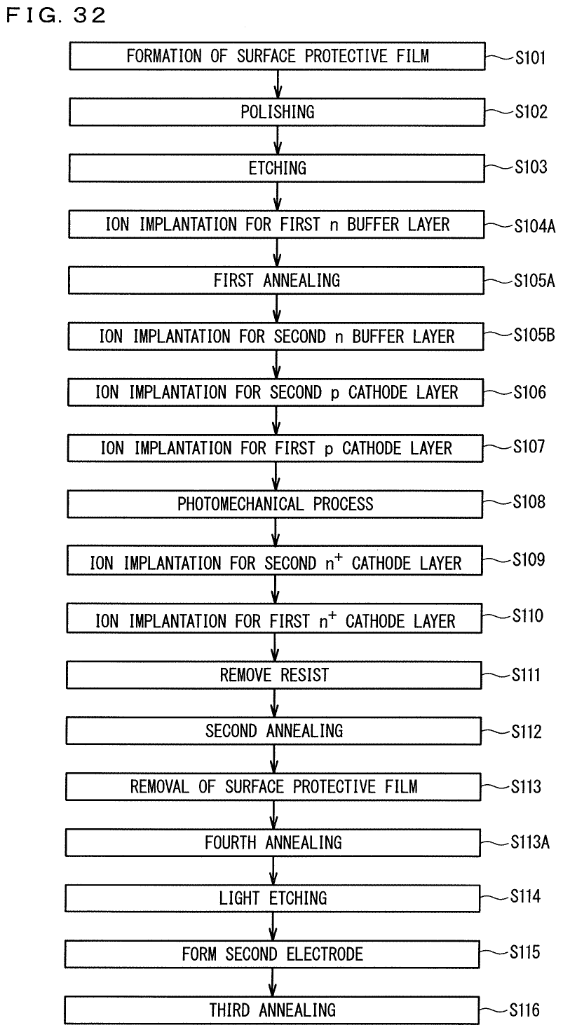

In a fifth preferred embodiment, a method for manufacturing the RFC diode 1003 according to the third preferred embodiment will be described. FIG. 32 is a flowchart illustrating a process of and after the forming process of the surface protective film 23 in the method for manufacturing the RFC diode 1003.

Steps S101 to 103 in FIG. 32 are similar to those in FIG. 31. After Step S103, ions for forming the first n buffer layer 81 are implanted in Step S104A. This ion implantation is also referred to as first ion implantation.

After Step S104A, annealing for activating the ions implanted in Step S104A is performed in Step S105A. This annealing is also referred to as first annealing. The first n buffer layer 81 is formed by the first annealing. The first annealing for forming the first n buffer layer 81 needs to be higher in temperature than fourth annealing for forming the second n buffer layer 82 described later.

After Step S105A, in Step S105B, ion implantation for forming the second n buffer layer 82 is performed. This ion implantation is also referred to as second ion implantation.

Steps S106 to S113 after Step S105B is similar to those in FIG. 31. Note that ion implantation for forming the second p cathode layer 102 in Step S106 is referred to as third ion implantation. Further, ion implantation for forming the first p cathode layer 101 in Step S107 is referred to as fourth ion implantation. Further, ion implantation for forming the second n+ cathode layer 92 in Step S109 is referred to as fifth ion implantation. Further, ion implantation for forming the first n+ cathode layer 91 in Step S110 is referred to as sixth ion implantation.

The second annealing in Step S112 forms the second n buffer layer 82, the second p cathode layer 102, the first p cathode layer 101, the second n+ cathode layer 92, and the first n+ cathode layer 91. In the present process, formation order of the first n buffer layer 81 and the second n buffer layer 82 is important. Further, setting of acceleration energy is important in ion implantation for forming the second n buffer layer 82.

After Step S113, the fourth annealing is performed in Step S113A. According to FIG. 20, annealing temperature in the fourth annealing process for setting the trap B as a main trap is higher than third annealing temperature and 370° C. or lower. By the fourth annealing, in the second n buffer layer 82, the trap B that is an interstitial Si pair is controlled to be a main trap.

Steps S114 to S116 after Step S113A is similar to those in FIG. 31. By the above, the RFC diode 1003 according to the third preferred embodiment is manufactured.

As an ion species for forming the first n buffer layer 81, phosphorus, arsenic, selenium, sulfur, or a proton (H+) is used. A proton or helium is used as an ion species for forming the second n buffer layer 82. A proton or helium can be introduced into Si by an irradiation technique using a cyclotron other than ion implantation.

In a case where a proton is used as an ion species for forming the first n buffer layer 81, when a proton is introduced into Si, a vacancy (v) generated at the time of introduction reacts with an impurity in Si to form a composite defect. Since the composite defect contains hydrogen, the composite defect serves as an electron supply source. Donor concentration increases due to increase in composite defect density by annealing, and donor concentration increases due to a mechanism that promotes a thermal donor conversion phenomenon caused by ion implantation/irradiation process. As a result, an n layer converted to a donor having impurity concentration higher than that of the n− drift layer 7 is formed as the first n buffer layer 81, which contributes to operation of a device.

On the other hand, composite defects formed when a proton is introduced into Si include a defect serving as a lifetime killer that reduces lifetime of a carrier. When a proton is used as an ion species for forming the first n buffer layer 81, the first annealing for forming the first n buffer layer 81 needs to be performed at higher temperature (375° C. or more and 425° C. or less, nitrogen atmosphere, 90 minutes or more) than the fourth annealing for forming the second n buffer layer 82 in consideration of removal of a defect that serves as a lifetime killer and stability of a profile in the first n buffer layer 81.

<E-2. Effect>

According to the method for manufacturing the RFC diode 1003 described in the fifth preferred embodiment, the first metal layer 5 and the surface protective film 23 are formed on the first main surface 21 of the semiconductor substrate 20 having the n− drift layer 7, thickness of the semiconductor substrate 20 is controlled to desired thickness after formation of the surface protective film 23, first ion implantation and first annealing for forming the first n buffer layer 81 on the second main surface 22 of the semiconductor substrate 20 are performed after control of thickness of the semiconductor substrate 20, second ion implantation for forming the second n buffer layer 82 on the second main surface 22 of the semiconductor substrate 20 is performed after the first annealing, third ion implantation for forming the second p cathode layer 102 on the second main surface 22 of the semiconductor substrate 20 is performed after the second ion implantation, fourth ion implantation for forming the first p cathode layer 101 on the second main surface 22 of the semiconductor substrate 20 is performed with acceleration energy smaller than that of the third ion implantation after the third ion implantation, fifth ion implantation for forming the second n+ cathode layer 92 on the second main surface 22 of the semiconductor substrate is performed after the fourth ion implantation, sixth ion implantation for forming the first n+ cathode layer 91 on the second main surface 22 of the semiconductor substrate 20 is performed with acceleration energy smaller than that of the fifth ion implantation after the fifth ion implantation, second annealing for activating ions implanted by the second, third, fourth, fifth, and sixth ion implantation is performed after the sixth ion implantation so that the second n buffer layer 82, the second p cathode layer 102, the first p cathode layer 101, the second n+ cathode layer 92, and the first n+ cathode layer 91 are formed, third annealing is performed in nitrogen atmosphere, the second metal layer 11 is formed on the second main surface 22 of the semiconductor substrate 20 after the third annealing, and fourth annealing is performed at 350° C. in nitrogen atmosphere after the second metal layer 11 is formed. By the above, since the first n buffer layer 81 and the second n buffer layer 82 in which the trap B of an interstitial Si pair is a main trap component are formed, the trade-off characteristic between the on-voltage V_{F} and the switching loss E_{REC} is controlled to the high-speed side regardless of a conventional lifetime control method, and reduction of off-loss, improvement of breakdown resistance, and thermal stability are realized.

### F. Sixth Preferred Embodiment

<F-1. Configuration>

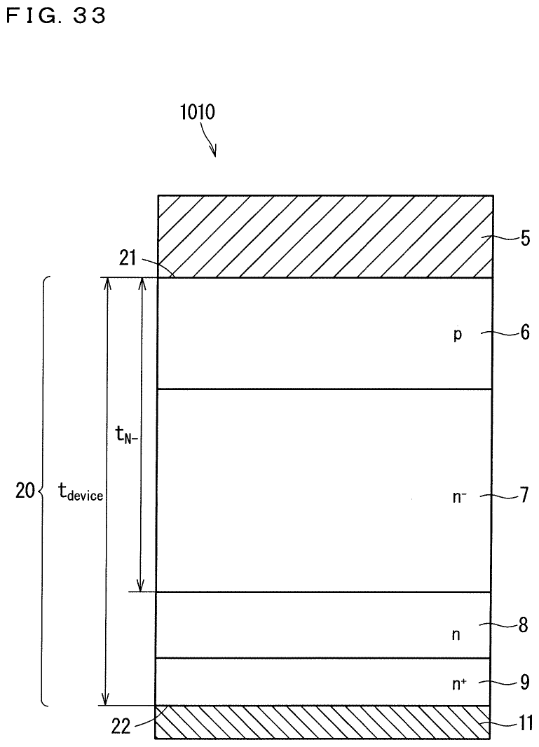

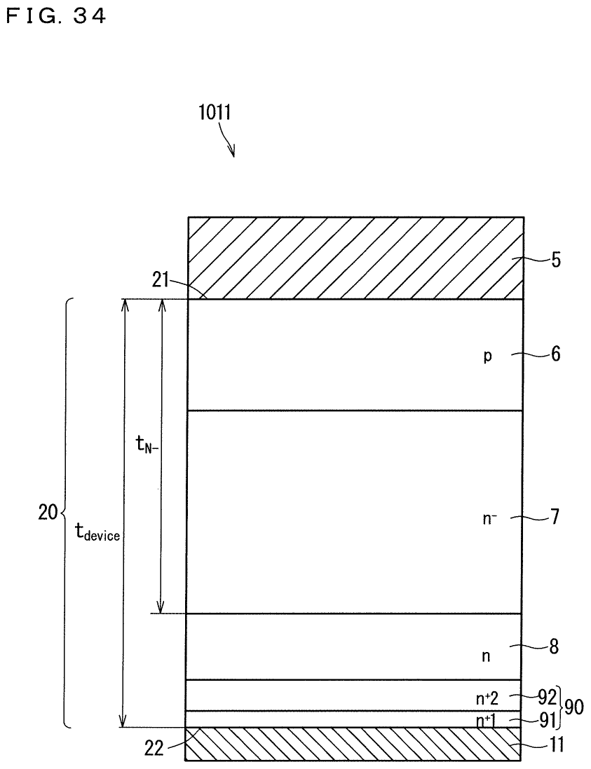

FIGS. 33 and 34 illustrate a cross-sectional configuration of a pin diode, which is an example of the power semiconductor device, taken along line A1-A1′ in FIG. 1. FIG. 33 is a cross-sectional view of a conventional pin diode 1010, and FIG. 34 is a cross-sectional view of a pin diode 1011 according to a sixth preferred embodiment. In the diagrams, the conventional pin diode 1010 may be referred to as Con. pin diode, and the pin diode 1011 according to the sixth preferred embodiment may be referred to as New pin diode 1.

The conventional pin diode 1010 illustrated in FIG. 33 is similar to a left-half configuration including the pin diode region 31 of the conventional RFC diode 1000 illustrated in FIG. 2. The pin diode 1011 of the sixth preferred embodiment illustrated in FIG. 34 has a similar configuration to a left-half including the pin diode region 31 of the RFC diode 1001 according to the first preferred embodiment illustrated in FIG. 3. A parameter of each layer of the pin diodes 1010 and 1011, which are not specifically mentioned below, are similar to those in the RFC diodes 1000 and 1001.

The n− drift layer 7 is formed using a Si wafer having impurity concentration Cₙ₋ of 1.0×10¹² atoms/cm³ or more and 1.0×10¹⁵ atoms/cm³ or less.

The p anode layer 6, the n buffer layer 8, the first n+ cathode layer 91, and the second n+ cathode layer 92 are the same as those in the first preferred embodiment.

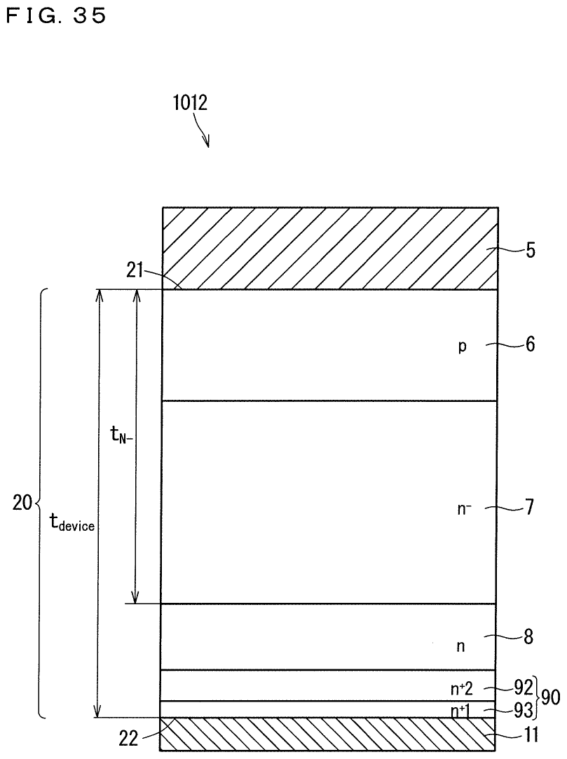

FIG. 35 is a cross-sectional view of a pin diode 1012 according to a variation of the sixth preferred embodiment taken along line A1-A1∝ of FIG. 1; Compared with the pin diode 1011, the pin diode 1012 includes a third n+ cathode layer 93 instead of the first n+ cathode layer 91. In the third n+ cathode layer 93, there are the traps A and B that can be detected by the PL method described in FIG. 5.

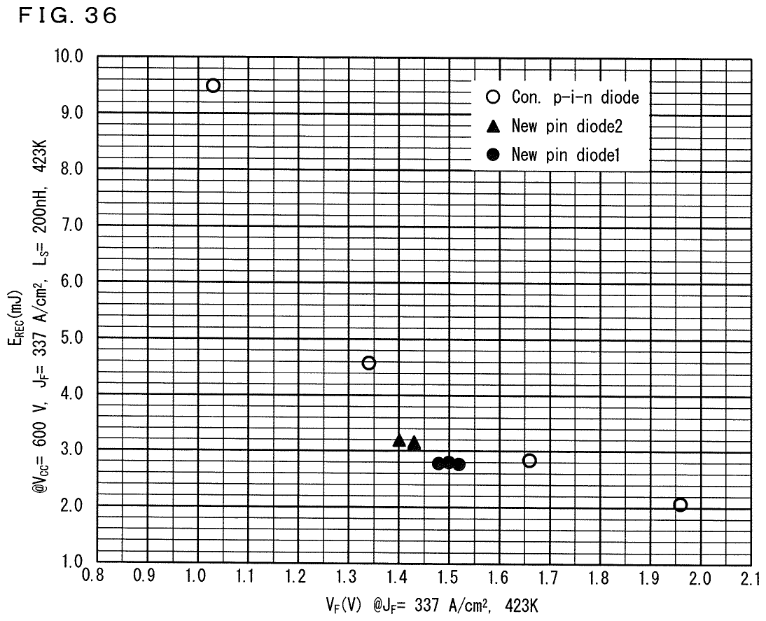

FIG. 36 illustrates a trade-off characteristic between the on-voltage V_{F} and the switching loss E_{REC} for the conventional pin diode 1010 and the pin diodes 1011 and 1012 according to the sixth preferred embodiment and the variation of the sixth preferred embodiment. A trade-off characteristic controlled by an electron beam is illustrated for the conventional pin diode 1010.

From FIG. 36, it can be seen that the pin diodes 1011 and 1012 according to the sixth preferred embodiment and the variation of the sixth preferred embodiment realize the high-speed side of a trade-off characteristic similar to that of the conventional pin diode 1010 controlled by an electron beam. This is because the pin diodes 1011 and 1012 according to the sixth preferred embodiment and the variation of the sixth preferred embodiment include the first n+ cathode layer 91 or the third n+ cathode layer 93 having the trap B similarly to the RFC diode 1001 according to the first preferred embodiment.

<F-2. Manufacturing Method>

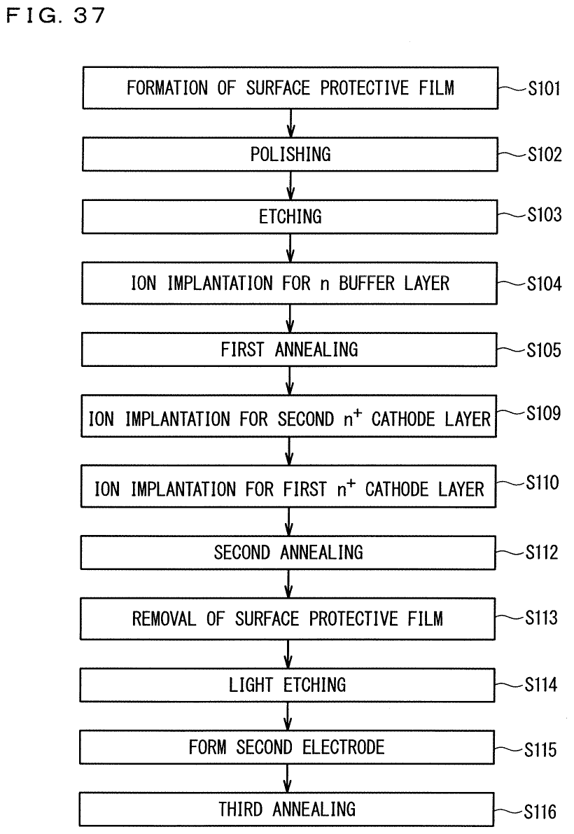

Hereinafter, a portion of the method for manufacturing the pin diode 1011 different from the method for manufacturing the RFC diode 1001 according to the first preferred embodiment will be described. FIG. 37 is a flowchart illustrating a process of and after a forming process of the surface protective film 23 in the method for manufacturing the pin diode 1011. The flowchart of FIG. 37 is obtained by deleting Steps S106 to S108 and Step S111 relating to formation of the first p cathode layer 101 and the second p cathode layer 102 and the photomechanical process in the flowchart relating to the method for manufacturing the RFC diode 1001 illustrated in FIG. 31.

<F-3 Effect>

Since the pin diode 1011 according to the sixth preferred embodiment includes the first n+ cathode layer 91 and the second n+ cathode layer 92 similar to those of the RFC diode 1001 according to the first preferred embodiment, the trade-off characteristic between the on-voltage V_{F} and the switching loss E_{REC} is controlled to the high-speed side regardless of a conventional lifetime control method, and low off-loss, improved breakdown resistance, and thermal stability are realized.

The pin diode 1012 according to the variation of the sixth preferred embodiment also includes the third n+ cathode layer 93 having the traps A and B similarly to the second n+ cathode layer 92 instead of the second n+ cathode layer 92, and thus has a similar effect to the pin diode 1011.

As described above, even in the case of the pin diode, it is possible to suppress influence of an impurity defect due to the Si material.

### G. Seventh Preferred Embodiment

<G-1. Configuration>

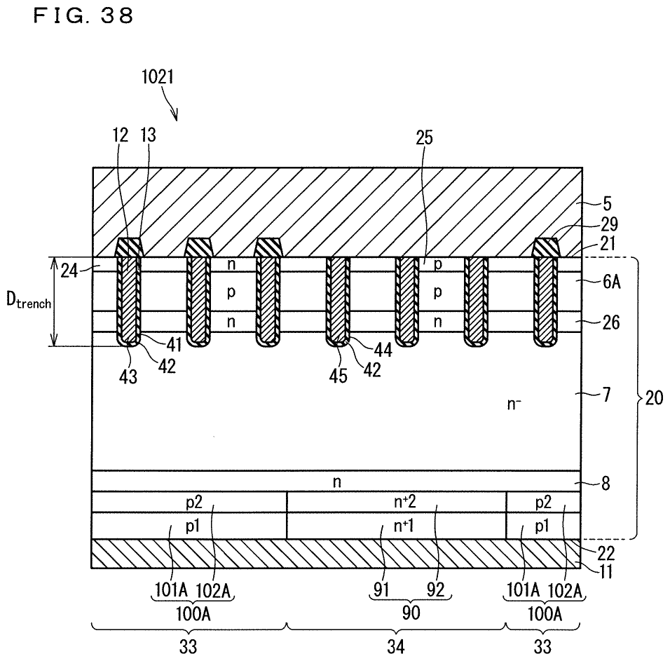

FIG. 38 is a cross-sectional view of an RC-IGBT 1021, which is the power semiconductor device according to a seventh preferred embodiment, taken along line A-A′ of FIG. 1. The RC-IGBT 1021 has a cathode structure similar to that of the RC-IGBT 1001 according to the first preferred embodiment.

As illustrated in FIG. 38, the RC-IGBT 1021 includes the semiconductor substrate 20, the first metal layer 5, and the second metal layer 11. The semiconductor substrate 20 has the first main surface 21 and the second main surface 22 facing each other. The first metal layer 5 is formed on the first main surface 21 of the semiconductor substrate 20, and the second metal layer 11 is formed on the second main surface 22 of the semiconductor substrate 20.

Further, the RC-IGBT 1021 is divided into an IGBT region 33 that operates as an IGBT in plan view and a diode region 34 that operates as a diode.

The semiconductor substrate 20 includes the n− drift layer 7, an n layer 26, a p base layer 6A, an n+ emitter layer 24, and a p+ layer 25. The n layer 26 is formed on the first main surface 21 side of the n− drift layer 7. The p base layer 6A is formed on the first main surface 21 side of the n layer 26. The n+ emitter layer 24 is formed on the first main surface 21 side of the p base layer 6A in the IGBT region 33. The p+ layer 25 is formed on the first main surface 21 side of the p base layer 6A in the diode region 34.

In the IGBT region 33, a trench 41 penetrating the n+ emitter layer 24, the p base layer 6A, and the n layer 26 from the first main surface 21 of the semiconductor substrate is formed. A gate electrode 43 is embedded in the trench 41 via a gate insulating film 42. An interlayer insulating film 29 for insulating the gate electrode 43 from the first metal layer 5 is formed on the gate electrode 43.

In the diode region 34, a trench 44 penetrating the p+ layer 25, the p base layer 6A, and the n layer 26 from the first main surface 21 of the semiconductor substrate 20 is formed. A dummy gate electrode 45 is embedded in the trench 44 via the gate insulating film 42. Unlike the trench 41, an internal electrode of the trench 44 serves as the dummy gate electrode 45 because the internal electrode is in contact with the emitter electrode 5 and has the same potential.

Furthermore, the semiconductor substrate 20 includes the n buffer layer 8, the n+ cathode layer 90, and a p collector layer 100A. The n buffer layer 8 is formed on the second main surface 22 side of the n− drift layer 7.

The n+ cathode layer 90 is formed in the diode region 34 and has a two-layer structure including the first n+ cathode layer 91 and the second n+ cathode layer 92. The second n+ cathode layer 92 is formed between the n buffer layer 8 and the second main surface 22 so as to be in contact with the n buffer layer 8. The first n+ cathode layer 91 is formed between and in contact with the second n+ cathode layer 92 and the second metal layer 11. A lower surface of the first n+ cathode layer 91 constitutes the second main surface of the semiconductor substrate 20.

The p collector layer 100A is formed in the IGBT region 33 and has a two-layer structure including a first p collector layer 101A and a second p collector layer 102A. The second p collector layer 102A is formed between the n buffer layer 8 and the second main surface 22 so as to be in contact with the n buffer layer 8. The first p collector layer 101A is formed between and in contact with the second p collector layer 102A and the second metal layer 11. A lower surface of the first p collector layer 101A constitutes the second main surface of the semiconductor substrate 20.

A parameter of each layer of the RC-IGBT 1021, which is not particularly mentioned below, is similar to the parameter of each corresponding layer in the first preferred embodiment. The n− drift layer 7, the n buffer layer 8, the first n+ cathode layer 91, and the second n+ cathode layer 92 are similar to those in the first preferred embodiment.

Peak impurity concentration of the p base layer 6A is 1.0×10¹⁶ atoms/cm³ or more and 1.0×10¹⁸ atoms/cm³ or less. A joining depth of the p base layer 6A is more than that of the n+ emitter layer 24 and less than that of the n layer 26.

Peak impurity concentration of the n layer 26 is 1.0×10¹⁵ atoms/cm³ or more and 1.0×10¹⁷ atoms/cm³ or less. A joining depth of the n layer 26 is set to be more than that of the p base layer 6A by about 0.5 μm or more and 1.0 μm or less.

Peak impurity concentration of the n+ emitter layer 24 is 1.0×10¹⁸ atoms/cm³ or more and 1.0×10²¹ atoms/cm³ or less. A joining depth of the n+ emitter layer 24 is 0.2 μm or more and 1.0 μm or less.

Impurity concentration on a surface of the p+ layer 25 in contact with the first metal layer 5, that is, the first main surface 21 is 1.0×10¹⁸ atoms/cm³ or more and 1.0×10²¹ atoms/cm³ or less. A joining depth of the p+ layer 25 is equal to or more than the joining depth of the n+ emitter layer 24.

A depth of the trenches 41 and 44, that is, a trench depth D_{trench} is more than that of the n layer 26.

The first p collector layer 101A has impurity concentration of 1.0×10¹⁷ atoms/cm³ or more and 1.0×10¹⁸ atoms/cm³ or less on a surface in contact with the second metal layer 11, that is, on the second main surface 22, and has a depth of 0.1 μm or more and 0.2 μm or less.

The second p collector layer 102A has peak impurity concentration of 1.0×10¹⁶ atoms/cm³ or more and 1.0×10²⁰ atoms/cm³ or less and depth of 0.3 μm or more and 0.5 μm or less.

Here, the first n+ cathode layer 91 and the second n+ cathode layer 92, and the first p collector layer 101A and the second p collector layer 102A satisfy relationships of Equations (1), (2), and (3). However, in Equation (1), Rₚ₁ is read as a range (m) of the first p collector layer 101A, and Rₚ₂ is read as a range (m) of the second p collector layer 102A. Further, in Equation (3), Dₚ₂ is read as the number of atoms (atoms/cm²) per unit area of the second p collector layer 102A.

<G-2. First Variation>

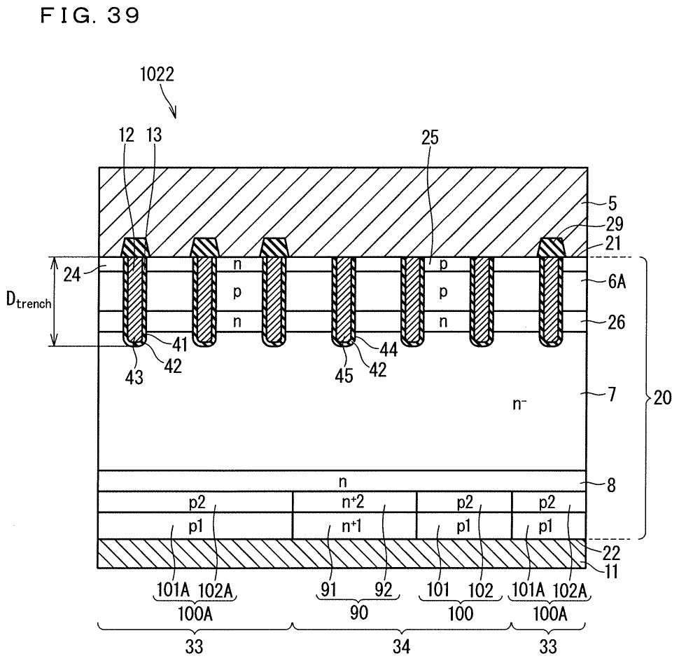

FIG. 39 is a cross-sectional view of an RC-IGBT 1022, which is the power semiconductor device according to a first variation of the seventh preferred embodiment, taken along line A-A′ of FIG. 1. The RC-IGBT 1022 is different from the RC-IGBT 1021 of the seventh preferred embodiment only in that the p cathode layer 100 is provided in a part of the diode region 34. That is, in the RC-IGBT 1022, the p cathode layer 100 which is a diffusion layer of a second conductivity type is provided in contact with the n buffer layer 8 and the second metal layer 11 even in a part of the diode region 34. In the RC-IGBT 1022, the p cathode layer 100 has a two-layer structure including the first p cathode layer 101 and the second p cathode layer 102.

The second p cathode layer 102 is formed between the n buffer layer 8 and the second main surface 22 so as to be in contact with the n buffer layer 8. The first p cathode layer 101 is formed between and in contact with the second p cathode layer 102 and the second metal layer 11. A lower surface of the first p cathode layer 101 constitutes the second main surface of the semiconductor substrate 20.

Parameters such as impurity concentration and a depth of the first p cathode layer 101 and the second p cathode layer 102 in the diode region 34 are similar to those of the first p collector layer 101A and the second p collector layer 102A in the IGBT region 33.

<G-3. Second Variation>

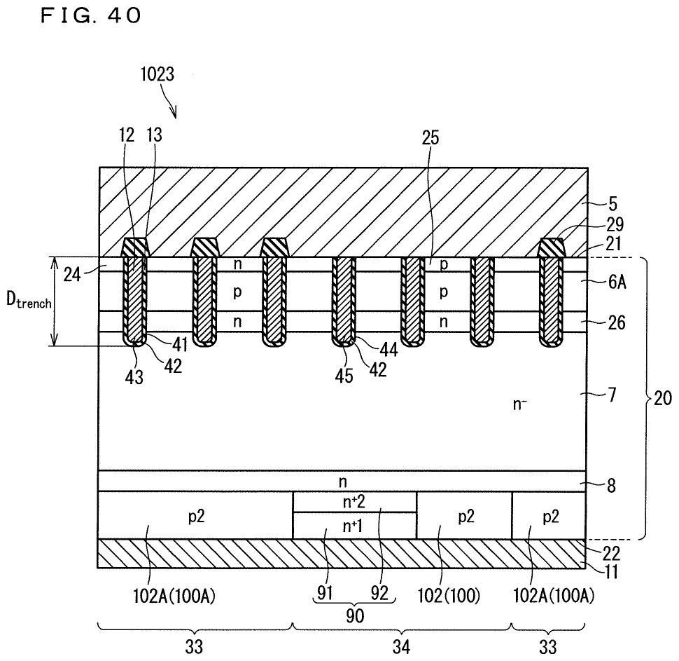

FIG. 40 is a cross-sectional view of an RC-IGBT 1023, which is the power semiconductor device according to a second variation of the seventh preferred embodiment, taken along line A-A′ of FIG. 1. The RC-IGBT 1023 is different from the RC-IGBT 1022 according to the first variation of the seventh preferred embodiment only in that the p collector layer 100A is composed of one layer of the second p collector layer 102A in the IGBT region 33, and the p cathode layer 100 is composed of one layer of the second p cathode layer 102 in the diode region 34.

In the second p collector layer 102A and the second p cathode layer 102 in the RC-IGBT 1023, impurity concentration on the second main surface 22 is 1.0×10¹⁷ atoms/cm³ or more and 1.0×10¹⁹ atoms/cm³ or less, and a depth is 0.3 μm or more and 0.5 μm or less.

<G-4. Effect>

In the RC-IGBTs 1021, 1022, and 1023 according to the seventh preferred embodiment and the first and second variations of the seventh preferred embodiment, similarly to the method for manufacturing the RFC diode 1001 described in the fourth preferred embodiment, a collector structure in the IGBT region 33 and a cathode structure in the diode region 34 are configured to satisfy relationships of Equations (1), (2), and (3). Therefore, also, in the RC-IGBTs 1021, 1022, and 1023, the trade-off characteristic between the on-voltage V_{F} and the switching loss E_{REC} is controlled to the high-speed side regardless of a conventional lifetime control method, and low off-loss, improvement in breakdown resistance, and thermal stability are realized.

### H. Eighth Preferred Embodiment

<H-1. Configuration>

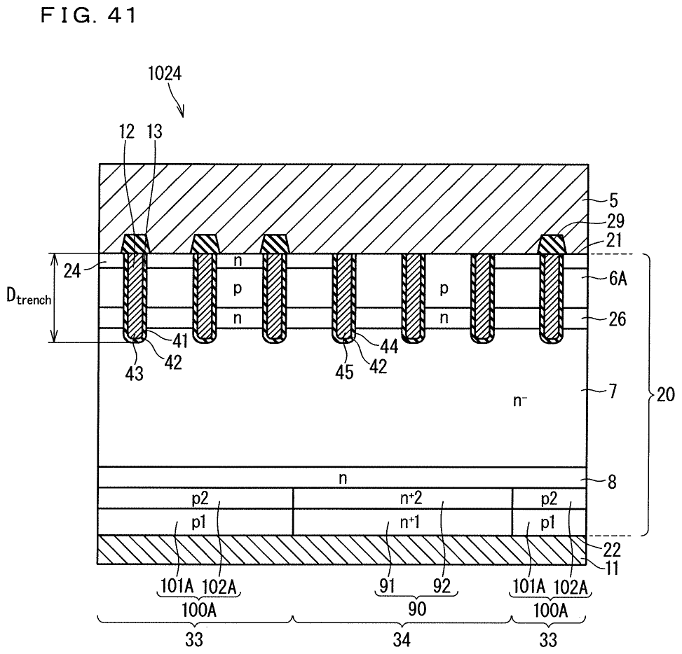

FIG. 41 is a cross-sectional view of an RC-IGBT 1024, which is the power semiconductor device according to an eighth preferred embodiment, taken along line A-A′ of FIG. 1. The RC-IGBT 1024 is different from the RC-IGBT 1021 according to the seventh preferred embodiment only in that the p+ layer 25 is not provided in the diode region 34. That is, in the RC-IGBT 1024, the p base layer 6A is in contact with the first metal layer 5 in the diode region 34.

Each diffusion layer and a trench of the RC-IGBT 1024 are set so as to have parameters below.

For the p base layer 6A in the IGBT region 33, parameters are as described below. Peak impurity concentration is 1.0×10¹⁶ atoms/cm³ or more and 1.0×10¹⁸ atoms/cm³ or less. A joining depth is more than that of the n+ emitter layer 24 and less than that of the n layer 26.

For the p base layer 6A in the diode region 34, parameters are as described below. Impurity concentration on a surface of the p base layer 6A in contact with the first metal layer 5, that is, the first main surface 21 is 1.0×10¹⁶ atoms/cm³ or more. Peak impurity concentration is 2.0×10¹⁶ atoms/cm³ or more and 1.0×10¹⁸ atoms/cm³ or less. A joining depth is more than that of the n+ emitter layer 24 and less than that of the n layer 26.

Other than the above, parameters regarding the n layer 26, the n+ emitter layer 24, the trench depth, the n buffer layer 8, the first n+ cathode layer 91, the second n+ cathode layer 92, the first p collector layer 101A, and the second p collector layer 102A are similar to those in the seventh preferred embodiment.

<H-2, First Variation>

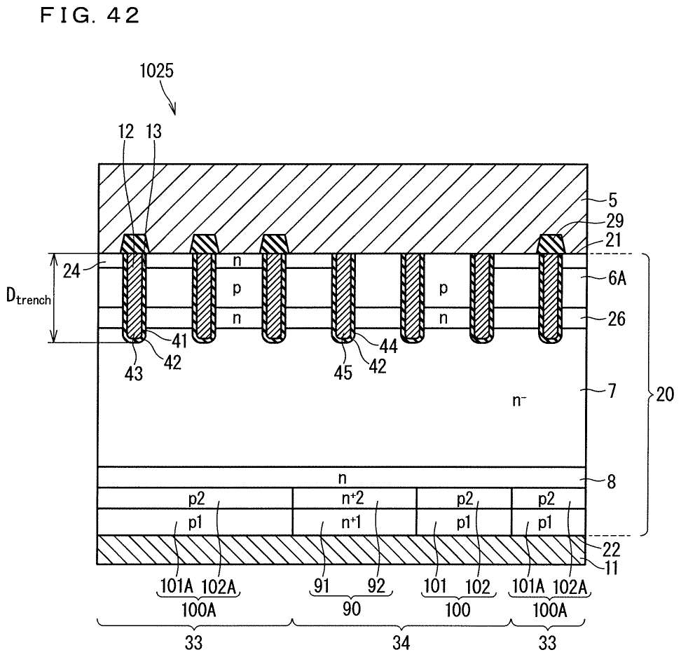

FIG. 42 is a cross-sectional view of an RC-IGBT 1025, which is the power semiconductor device according to a first variation of the eighth preferred embodiment, taken along line A-A′ of FIG. 1. The RC-IGBT 1025 is different from the RC-IGBT 1021 of the seventh preferred embodiment only in that the p cathode layer 100 is provided in a part of the diode region 34. In the RC-IGBT 1022, the p cathode layer 100 has a two-layer structure including the first p cathode layer 101 and the second p cathode layer 102.

The second p cathode layer 102 is formed between the n buffer layer 8 and the second main surface 22 so as to be in contact with the n buffer layer 8. The first p cathode layer 101 is formed between and in contact with the second p cathode layer 102 and the second metal layer 11. A lower surface of the first p cathode layer 101 constitutes the second main surface of the semiconductor substrate 20.

Parameters such as impurity concentration and a depth of the first p cathode layer 101 and the second p cathode layer 102 in the diode region 34 are similar to those of the first p collector layer 101A and the second p collector layer 102A in the IGBT region 33.

<H-3. Second Variation>

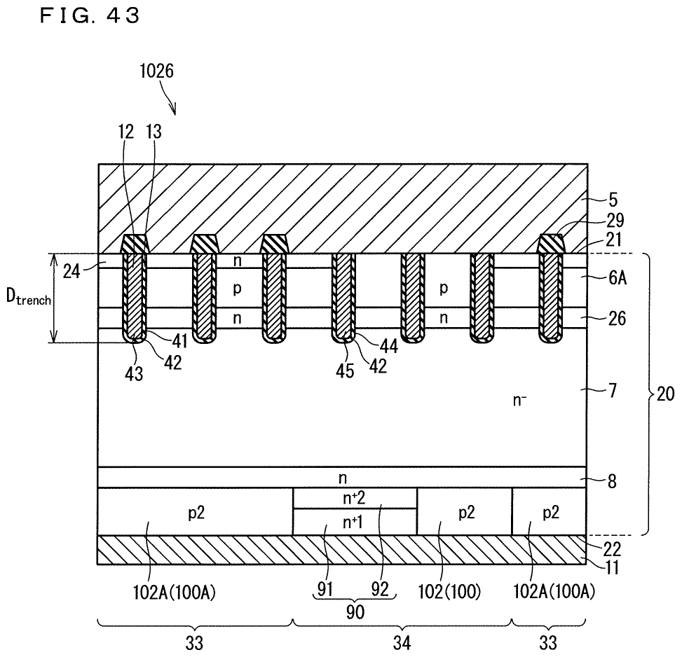

FIG. 43 is a cross-sectional view of an RC-IGBT 1026, which is the power semiconductor device according to a second variation of the eighth preferred embodiment, taken along line A-A′ of FIG. 1. The RC-IGBT 1026 is different from the RC-IGBT 1025 according to the first variation of the eighth preferred embodiment only in that the p collector layer 100A is composed of one layer of the second p collector layer 102A in the IGBT region 33, and the p cathode layer 100 is composed of one layer of the second p cathode layer 102 in the diode region 34.

In the second p collector layer 102A and the second p cathode layer 102 in the RC-IGBT 1026, surface impurity concentration on the second main surface 22 is 1.0×10¹⁷ atoms/cm³ or more and 1.0×10¹⁹ atoms/cm³ or less, and a depth is 0.3 μm or more and 0.5 or less.

<H-4. Effect>

In the RC-IGBTs 1024, 1025, and 1026 according to the eighth preferred embodiment and the first and second variations of the eighth preferred embodiment, similarly to the method for manufacturing the RFC diode 1001 described in the fourth preferred embodiment, a collector structure in the IGBT region 33 and a cathode structure in the diode region 34 are configured to satisfy relationships of Equations (1), (2), and (3). Therefore, also in the RC-IGBTs 1024, 1025, and 1026, the trade-off characteristic between the on-voltage V_{F} and the switching loss E_{REC} can be controlled to the high-speed side regardless of a conventional lifetime control method, and low off-loss, improvement in breakdown resistance, and thermal stability can be realized.

Further, since the p+ layer 25 is not provided, the diode region 34 of the RC-IGBTs 1024, 1025, and 1026 can achieve the same performance as the pin diode region 31 of the RFC diode 1001 according to the first preferred embodiment illustrated in FIG. 3 and the pin diode 1011 according to the sixth preferred embodiment illustrated in FIG. 34.

### I. Ninth Preferred Embodiment

<I-1. Configuration>

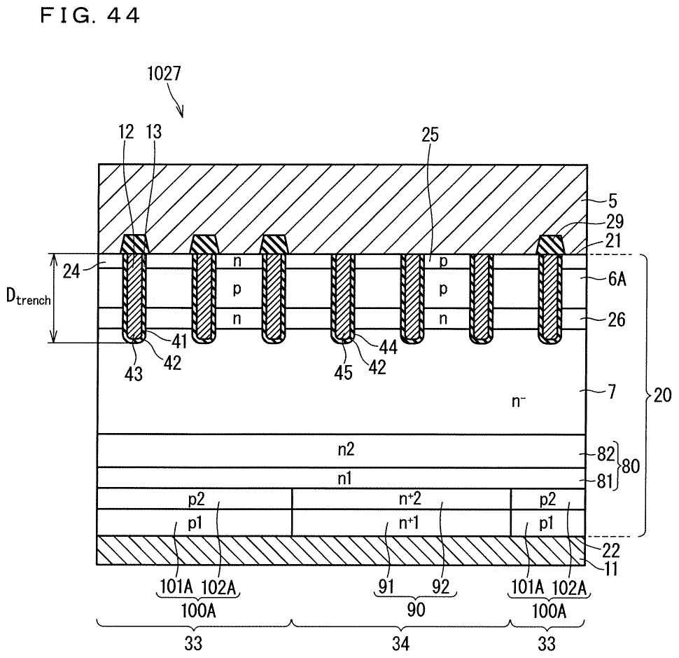

FIG. 44 is a cross-sectional view of an RC-IGBT 1027, which is the power semiconductor device according to a ninth preferred embodiment, taken along line A-A′ of FIG. 1. The RC-IGBT 1027 is different from the RC-IGBT 1021 of the seventh preferred embodiment only in that the n buffer layer 80 has a two-layer structure of the first n buffer layer 81 and the second n buffer layer 82 as in the RFC diode 1003 according to the third embodiment.

Parameters of the first n buffer layer 81 and the second n buffer layer 82 are similar to those in the RFC diode 1003 according to the third preferred embodiment.

<I-2. First Variation>

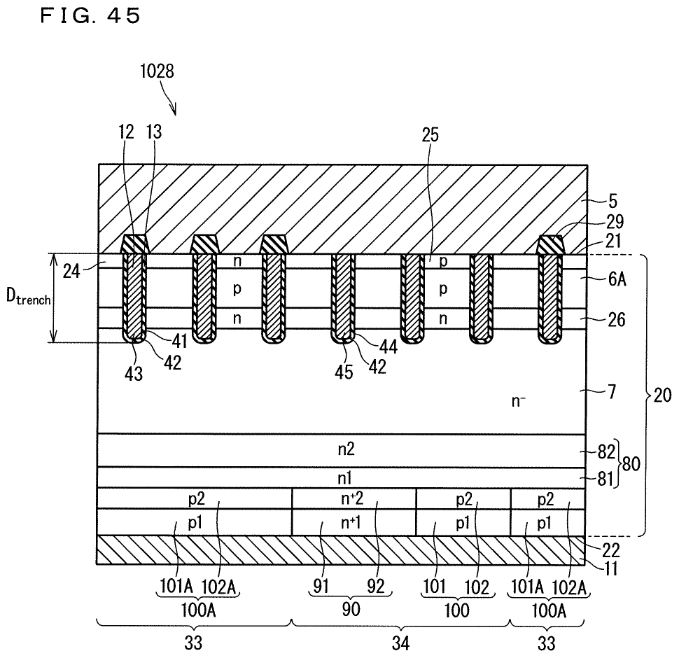

FIG. 45 is a cross-sectional view of an RC-IGBT 1028, which is the power semiconductor device according to a first variation of the ninth preferred embodiment, taken along line A-A′ of FIG. 1. The RC-IGBT 1028 is different from the RC-IGBT 1027 of the ninth preferred embodiment only in that the p cathode layer 100 is provided in a part of the diode region 34. In the RC-IGBT 1028, the p cathode layer 100 has a two-layer structure including the first p cathode layer 101 and the second p cathode layer 102.

The second p cathode layer 102 is formed between the n buffer layer 8 and the second main surface 22 so as to be in contact with the n buffer layer 8. The first p cathode layer 101 is formed between and in contact with the second p cathode layer 102 and the second metal layer 11. A lower surface of the first p cathode layer 101 constitutes the second main surface of the semiconductor substrate 20.

Parameters such as impurity concentration and a depth of the first p cathode layer 101 and the second p cathode layer 102 in the diode region 34 are similar to those of the first p collector layer 101A and the second p collector layer 102A in the IGBT region 33.

<1-3. Second Variation>

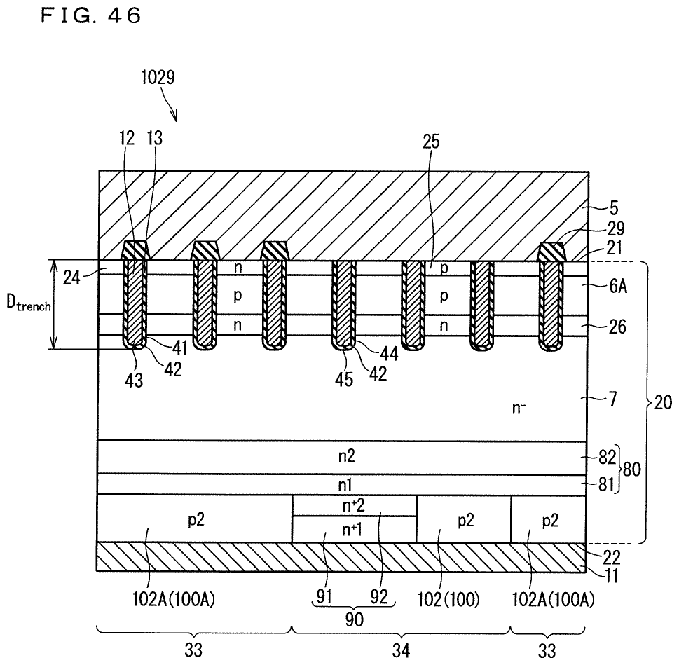

FIG. 46 is a cross-sectional view of an RC-IGBT 1029, which is the power semiconductor device according to a second variation of the ninth preferred embodiment, taken along line A-A′ of FIG. 1. The RC-IGBT 1029 is different from the RC-IGBT 1028 according to the first variation of the ninth preferred embodiment only in that the p collector layer 100A is composed of one layer of the second p collector layer 102A in the IGBT region 33, and the p cathode layer 100 is composed of one layer of the second p cathode layer 102 in the diode region 34.

In the second p collector layer 102A and the second p cathode layer 102 in the RC-IGBT 1029, surface impurity concentration on the second main surface 22 is 1.0×10¹⁷ atoms/cm³ or more and 1.0×10¹⁹ atoms/cm³ or less, and a depth is 0.3 μm or more and 0.5 μm or less.

<1-4. Effect>

The RC-IGBTs 1027, 1028, and 1029 according to the ninth preferred embodiment and the first and second variations of the ninth preferred embodiment include the first n buffer layer 81 and the second n buffer layer 82 similar to the RFC diode 1003 according to the third preferred embodiment. In the second n buffer layer 82, the trap B by an interstitial Si pair is a main trap component. Therefore, according to the RC-IGBTs 1027, 1028, and 1029, as similar to the RFC diode 1003, a trade-off characteristic between the on-voltage V_{F} and the switching loss E_{REC} is controlled to the high-speed side regardless of a conventional lifetime control method, and low off-loss, improvement in breakdown resistance, and thermal stability are realized.

### J. Tenth Preferred Embodiment

<J-1. Configuration>

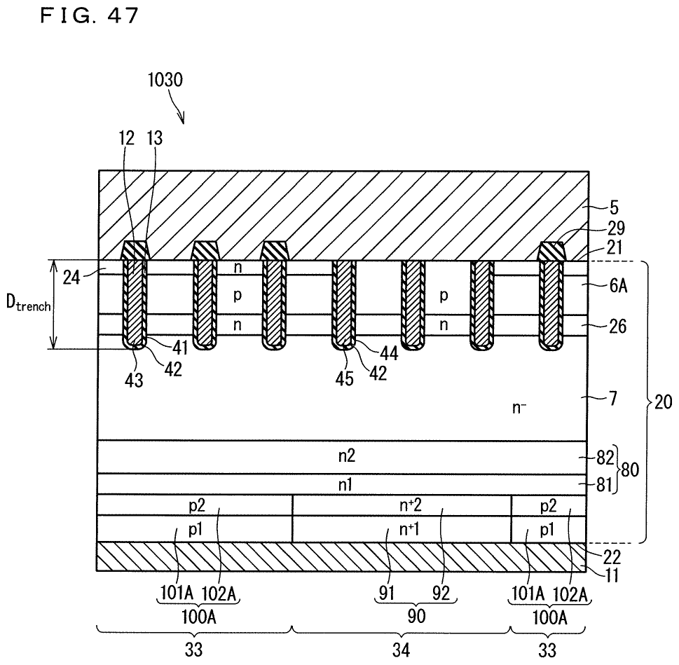

FIG. 47 is a cross-sectional view of an RC-IGBT 1030, which is the power semiconductor device according to a tenth preferred embodiment, taken along line A-A′ of FIG. 1. The RC-IGBT 1030 is different from the RC-IGBT 1027 according to the ninth preferred embodiment only in that the p+ layer 25 is not provided in the diode region 34. That is, in the RC-IGBT 1030, the p base layer 6A is in contact with the first metal layer 5 in the diode region 34.

Parameters regarding each diffusion layer and a trench of the RC-IGBT 1030 are as described below. The p base layer 6A in the IGBT region 33 and the diode region 34 is similar to that of the eighth preferred embodiment. The n layer 26, the n+ emitter layer 24, the trench depth D_{trench}, the first n buffer layer 81, the second n buffer layer 82, the first n+ cathode layer 91, the second n+ cathode layer 92, the first p collector layer 101A, and the second p collector layer 102A are similar to those in the ninth preferred embodiment.

<J-2. First Variation>

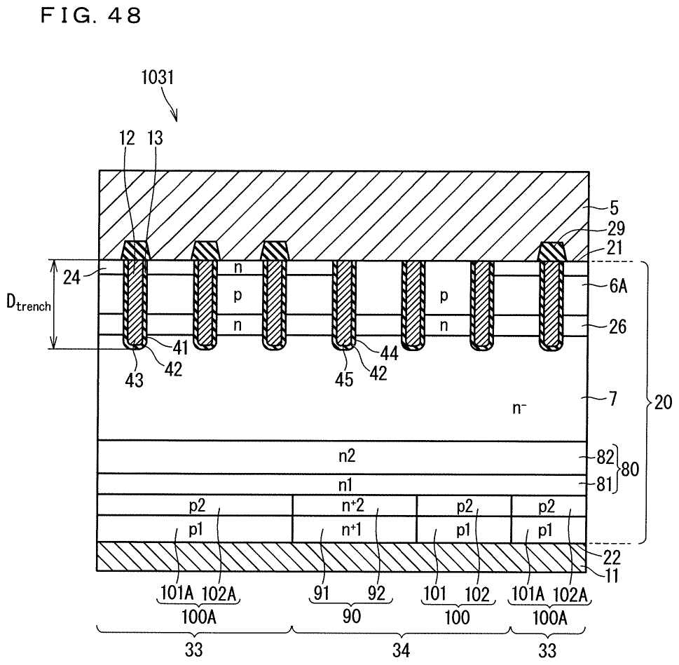

FIG. 48 is a cross-sectional view of an RC-IGBT 1031, which is the power semiconductor device according to a first variation of the tenth preferred embodiment, taken along line A-A′ of FIG. 1. The RC-IGBT 1031 is different from the RC-IGBT 1030 of the tenth preferred embodiment only in that the p cathode layer 100 is provided in a part of the diode region 34. In the RC-IGBT 1030, the p cathode layer 100 has a two-layer structure including the first p cathode layer 101 and the second p cathode layer 102.

The second p cathode layer 102 is formed between the n buffer layer 8 and the second main surface 22 so as to be in contact with the n buffer layer 8. The first p cathode layer 101 is formed between and in contact with the second p cathode layer 102 and the second metal layer 11. A lower surface of the first p cathode layer 101 constitutes the second main surface of the semiconductor substrate 20.

Parameters such as impurity concentration and a depth of the first p cathode layer 101 and the second p cathode layer 102 in the diode region 34 are similar to those of the first p collector layer 101A and the second p collector layer 102A in the IGBT region 33.

<J-3. Second Variation>

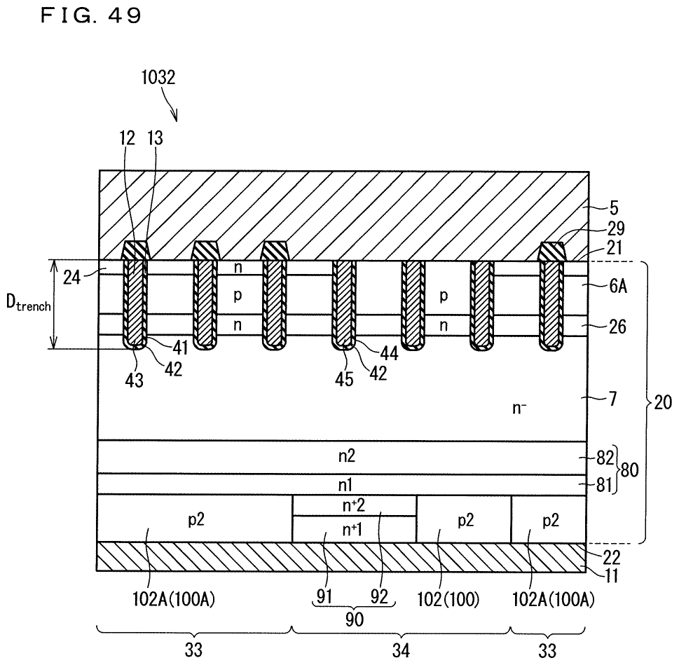

FIG. 49 is a cross-sectional view of an RC-IGBT 1032, which is the power semiconductor device according to a second variation of the tenth preferred embodiment, taken along line A-A′ of FIG. 1. The RC-IGBT 1032 is different from the RC-IGBT 1031 according to the first variation of the tenth preferred embodiment only in that the p collector layer 100A is composed of one layer of the second p collector layer 102A in the IGBT region 33, and the p cathode layer 100 is composed of one layer of the second p cathode layer 102 in the diode region 34.

In the second p collector layer 102A and the second p cathode layer 102 in the RC-IGBT 1031, impurity concentration on the second main surface 22 is 1.0×10¹⁷ atoms/cm³ or more and 1.0×10¹⁹ atoms/cm³ or less, and a depth is 0.3 μm or more and 0.5 μm or less.

<J-4. Effect>

The RC-IGBTs 1030, 1031, and 1032 according to the tenth preferred embodiment and the first and second variations of the tenth preferred embodiment include the first n buffer layer 81 and the second n buffer layer 82 similar to the RFC diode 1003 according to the third preferred embodiment. In the second n buffer layer 82, the trap B by an interstitial Si pair is a main trap component. Therefore, according to the RC-IGBTs 1027, 1028, and 1029, as similar to the RFC diode 1003, a trade-off characteristic between the on-voltage V_{F} and the switching loss E_{REC} is controlled to the high-speed side regardless of a conventional lifetime control method, and low off-loss, improvement in breakdown resistance, and thermal stability are realized.

Further, since the p+ layer 25 is not provided, the diode region 34 of the RC-IGBTs 1030, 1031, and 1032 can achieve the same performance as the pin diode region 31 of the RFC diode 1001 according to the first preferred embodiment illustrated in FIG. 3 and the pin diode 1011 according to the sixth preferred embodiment illustrated in FIG. 34.

### K. Eleventh Preferred Embodiment

<K-1. Configuration>

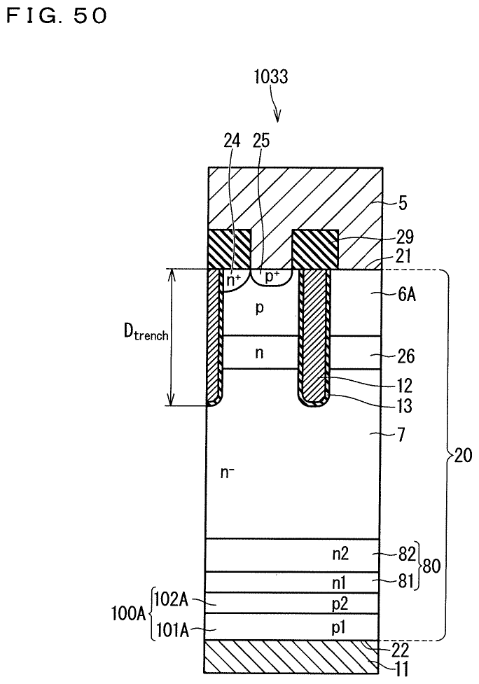

FIG. 50 is a cross-sectional view of an IGBT 1033, which is the power semiconductor device according to an eleventh preferred embodiment, taken along line A-A′ of FIG. 1. The IGBT 1033 has a trench gate structure.

The IGBT 1033 is similar in configuration to the IGBT region 33 of the RC-IGBT 1027 according to the ninth preferred embodiment.

The n− drift layer 7 in the IGBT 1033 is similar to the n− drift layer 7 in the RC-IGBT 1027 according to the ninth preferred embodiment.

In the IGBT 1033, a part of the gate electrode 43 in the trench 41 has the same potential as the first metal layer 5 which is the emitter potential. By the above, saturation current density of the IGBT is suppressed. Further, by controlling a capacitance characteristic, oscillation in a no-load short-circuit state is suppressed. As a result, short circuit tolerance is improved, and lower ON voltage is realized by improving carrier concentration on the emitter side.

The p base layer 6A, the n layer 26, the n+ emitter layer 24, the p+ layer 25, the first n buffer layer 81, the second n buffer layer 82, the first p collector layer 101A, the second p collector layer 102A, and the trench depth D_{trench} in the IGBT 1033 are similar to those in the RC-IGBT 1027 according to the ninth preferred embodiment.

<K-2. Effect>

The IGBT 1033, which is the power semiconductor device according to the eleventh preferred embodiment, includes the semiconductor substrate 20 having the first main surface 21 and the second main surface 22 facing each other, the first metal layer 5 provided on the first main surface 21 of the semiconductor substrate 20, and the second metal layer 11 provided on the second main surface 22 of the semiconductor substrate 20. The semiconductor substrate 20 includes the n− drift layer 7 which is a drift layer of a first conductivity type, the n buffer layer 8 which is a buffer layer of a first conductivity type provided between the n− drift layer 7 and the second main surface 22, and the p collector layer 100A which is a collector layer of a second conductivity type provided between the n buffer layer 8 and the second main surface 22. The n buffer layer 8 includes the first n buffer layer 81 which is a first buffer layer in contact with the second metal layer 11 and the second n buffer layer 82 which is a second buffer layer in contact with the n− drift layer 7. A crystal defect in the second n buffer layer 82 is the trap B which is a second lattice defect and the trap C which is a third lattice defect detected by a photoluminescence method. As described above, the IGBT 1033 includes the first n buffer layer 81 and the second n buffer layer 82 similar to the RFC diode 1003 according to the third preferred embodiment. In the second n buffer layer 82, the trap B by an interstitial Si pair is a main trap component. Therefore, according to the IGBT 1033, as similar to the RFC diode 1003, a trade-off characteristic between the on-voltage V_{F} and the switching loss E_{REC} is controlled to the high-speed side regardless of a conventional lifetime control method, and low off-loss, improvement in breakdown resistance, and thermal stability are realized.

Note that, preferred embodiments can be freely combined with each other, and each preferred embodiment can be appropriately modified or omitted.

While the disclosure has been shown and described in detail, the foregoing description is in all aspects illustrative and not restrictive. It is therefore understood that numerous modifications and variations can be devised.

What is claimed is:

1. A power semiconductor device comprising:
a semiconductor substrate having a first main surface and a second main surface facing each other;
a first metal layer provided on the first main surface of the semiconductor substrate; and
a second metal layer provided on the second main surface of the semiconductor substrate, wherein
the semiconductor substrate includes
a drift layer of a first conductivity type,
a buffer layer of a first conductivity type provided between the drift layer and the second main surface, and
a diffusion layer provided between and in contact with the buffer layer and the second metal layer, and
has a partial region in plan view being a diode region that operates as a diode,
the diffusion layer includes a cathode layer of a first conductivity type provided in contact with the buffer layer and the second metal layer in at least a part of the diode region,
the cathode layer of a first conductivity type includes
a first cathode layer that has one impurity concentration peak point and is in contact with the second metal layer, and
a second cathode layer having one impurity concentration peak point and provided between the first cathode layer and the buffer layer so as to be in contact with the buffer layer, and
crystal defect density of the first cathode layer is higher than crystal defect density of another one of the diffusion layer.

2. The power semiconductor device according to claim 1, wherein
a crystal defect in the first cathode layer is a first lattice defect and a second lattice defect detected by a photoluminescence method.

3. The power semiconductor device according to claim 2, wherein
photon energy of the second lattice defect is 1.018 eV.

4. The power semiconductor device according to claim 2, wherein
photon energy of the first lattice defect is 0.969 eV.

5. The power semiconductor device according to claim 1, wherein
a dose amount of the first cathode layer is 0.3 times or more a dose amount of the second cathode layer.

6. The power semiconductor device according to claim 1, wherein
a transistor region operating as a transistor is alternately arranged with the diode region in plan view, and
the diffusion layer includes a diffusion layer of a second conductivity type provided in contact with the buffer layer and the second metal layer in the transistor region.

7. The power semiconductor device according to claim 6, wherein
the diffusion layer of a second conductivity type includes
a first diffusion layer that has one impurity concentration peak point and is in contact with the second metal layer, and
a second diffusion layer that has one impurity concentration peak point and is provided between the first diffusion layer and the buffer layer so as to be in contact with the buffer layer.

8. The power semiconductor device according to claim 7, wherein
a dose amount of the second cathode layer is twice or more a dose amount of the second diffusion layer.

9. The power semiconductor device according to claim 6, wherein
the diffusion layer of a second conductivity type has one impurity concentration peak point.

10. The power semiconductor device according to claim 7, wherein
the buffer layer includes
a first buffer layer that has one impurity concentration peak point and is in contact with the diffusion layer, and
a second buffer layer that has one impurity concentration peak point and is in contact with the drift layer, and
a crystal defect in the second buffer layer is a second lattice defect and a third lattice defect detected by a photoluminescence method.

11. The power semiconductor device according to claim 10, wherein
photon energy of the second lattice defect is 1.018 eV,
photon energy of the third lattice defect is 1.039 eV, and
in the second buffer layer, photoluminescence intensity of the second lattice defect is higher than photoluminescence intensity of the third lattice defect.

12. The power semiconductor device according to claim 10, wherein
peak impurity concentration of the second buffer layer is 0.01 times or less peak impurity concentration of the first buffer layer.

13. The power semiconductor device according to claim 1, further comprising an anode layer of a second conductivity type provided between the drift layer and the first main surface.

14. The power semiconductor device according to claim 6, further comprising a base layer of a second conductivity type provided between the drift layer and the first main surface in the diode region.

15. The power semiconductor device according to claim 14, wherein
the diffusion layer of a second conductivity type is provided in contact with the buffer layer and the second metal layer even in a part of the diode region.

16. The power semiconductor device according to claim 14, wherein
the base layer is in contact with the first metal layer.

17. A power semiconductor device comprising:
a semiconductor substrate having a first main surface and a second main surface facing each other;
a first metal layer provided on the first main surface of the semiconductor substrate; and
a second metal layer provided on the second main surface of the semiconductor substrate, wherein
the semiconductor substrate includes
a drift layer of a first conductivity type,
a buffer layer of a first conductivity type provided between the drift layer and the second main surface, and
a collector layer of a second conductivity type provided between the buffer layer and the second main surface,
the buffer layer includes
a first buffer layer in contact with the second metal layer, and
a second buffer layer in contact with the drift layer, and
a crystal defect in the second buffer layer is a second lattice defect and a third lattice defect detected by a photoluminescence method.

18. A method for manufacturing the power semiconductor device according to claim 7, the method comprising:
forming a first metal layer and a surface protective film on a first main surface of a semiconductor substrate having a drift layer of a first conductivity type;
controlling thickness of the semiconductor substrate to desired thickness after formation of the surface protective film;
performing first ion implantation and first annealing for forming a buffer layer of a first conductivity type on the second main surface of the semiconductor substrate after control of thickness of the semiconductor substrate;
performing, after the first annealing, second ion implantation for forming a second diffusion layer of a second conductivity type on the second main surface of the semiconductor substrate;
performing, after the second ion implantation, third ion implantation for forming a first diffusion layer of a second conductivity type on the second main surface of the semiconductor substrate with acceleration energy smaller than acceleration energy of the second ion implantation;
performing, after the third ion implantation, fourth ion implantation for forming a second cathode layer of a first conductivity type on the second main surface of the semiconductor substrate;
performing, after the fourth ion implantation, fifth ion implantation for forming a first cathode layer of a first conductivity type on the second main surface of the semiconductor substrate with acceleration energy smaller than acceleration energy of the fourth ion implantation;
forming the second diffusion layer, the first diffusion layer, the second cathode layer, and the first cathode layer by performing second annealing for activating ions implanted by the second, third, fourth, and fifth ion implantation after the fifth ion implantation;
forming a second metal layer on the second main surface of the semiconductor substrate after the second annealing; and
performing, after formation of the second metal layer, third annealing at 350° C. in nitrogen atmosphere.

19. A method for manufacturing the power semiconductor device according to claim 10, the method comprising:
forming a first metal layer and a surface protective film on a first main surface of a semiconductor substrate having a drift layer of a first conductivity type;
controlling thickness of the semiconductor substrate to desired thickness after formation of the surface protective film;
performing first ion implantation and first annealing for forming a first buffer layer of a first conductivity type on the second main surface of the semiconductor substrate after control of thickness of the semiconductor substrate;
performing, after the first annealing, second ion implantation for forming a second buffer layer of a first conductivity type on the second main surface of the semiconductor substrate;
performing, after the second ion implantation, third ion implantation for forming a second diffusion layer of a second conductivity type on the second main surface of the semiconductor substrate;
performing, after the third ion implantation, fourth ion implantation for forming a first diffusion layer of a second conductivity type on the second main surface of the semiconductor substrate with acceleration energy smaller than acceleration energy of the third ion implantation;
performing, after the fourth ion implantation, fifth ion implantation for forming a second cathode layer of a first conductivity type on the second main surface of the semiconductor substrate;
performing, after the fifth ion implantation, sixth ion implantation for forming a first cathode layer of a first conductivity type on the second main surface of the semiconductor substrate with acceleration energy smaller than acceleration energy of the fifth ion implantation;
forming a second buffer layer, the second diffusion layer, the first diffusion layer, the second cathode layer, and the first cathode layer by performing second annealing for activating ions implanted by the second, third, fourth, fifth, and sixth ion implantation after the sixth ion implantation;
performing third annealing in nitrogen atmosphere;
forming a second metal layer on the second main surface of the semiconductor substrate after the third annealing; and
performing fourth annealing at 350° C. in nitrogen atmosphere after formation of the second metal layer.

20. The method for manufacturing the power semiconductor device according to claim 19, wherein
a temperature of the third annealing is 350° C. or more and 370° C. or less.
